(19) United States
(12) Patent Application Publication
(10) Pub. No.: US 2025/0221228 A1
(43) Pub. Date: Jul. 3, 2025

(54) DISPLAY DEVICE

(71) Applicant: LG Display Co., Ltd., Seoul (KR)

(72) Inventors: ChaeKyung LIM, Paju-si (KR); Youngsub SHIN, Paju-si (KR); Seungcheol YOU, Paju-si (KR)

(21) Appl. No.: 19/002,231

(22) Filed: Dec. 26, 2024

(30) Foreign Application Priority Data
Dec. 29, 2023 (KR) 10-2023-0196250

(51) Int. Cl. H10K 59/38; C09B 47/30; C09B 57/00; G09G 3/32; G09G 3/3233; H10K 59/80

(52) U.S. Cl. CPC H10K 59/38; C09B 47/30; C09B 57/00; H10K 59/8792; G09G 3/32; G09G 3/3233; G09G 2300/0842

(57) ABSTRACT

Provided is a display device, in which reflective visibility is improved and edge blemishes are reduced or prevented by applying a color filter composition including a dye and a pigment to color filters disposed on a red emitting element and a green emitting element.

### CROSS REFERENCE TO RELATED APPLICATION

This application claims priority and benefit from Korean Patent Application No. 10-2023-0196250, filed on Dec. 29, 2023, which is hereby incorporated by reference for all purposes as if fully set forth herein, as if fully set forth herein.

### BACKGROUND

### Technical Field

Embodiments relate to a display device.

### Description of the Related Art

Image display devices that reproduce various information on a screen are a key technology in the information and communication era, and are evolving toward having a thinner profile, lighter weight, higher portability, and higher performance. As a result, organic light-emitting display devices that display images by controlling the amount of light emitted by a light-emitting layer have come to prominence as flat panel display devices that may reduce the drawbacks, e.g., the weight and volume, of cathode ray tubes (CRTs).

Such organic light-emitting display devices each have polarizers including a circular polarizer and a linear polarizer to achieve the blackness of the organic light-emitting display device and to reduce external light reflection so as to improve visibility.

On the other hand, the operating environments of display devices are becoming more diverse, and even operation in high-temperature or high-humidity operating environments is becoming more common, and the bezels surrounding the display panel of display devices are becoming narrower. Therefore, ensuring the reliability of the operation of display devices in various operating environments is recognized as an important undertaking.

However, some display devices may exhibit blemishes or differences in reflective color tone around the edges of the display depending on the operating environment.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

Therefore, the inventors of the present disclosure recognized the limitations or problems mentioned above and other limitations associated with the related art, and conducted various experiments to implement a display device whose viewing angle can be controlled.

Embodiments may provide a display device able to reduce or prevent the occurrence of blemishes around the edges of a display device without a polarizer.

Embodiments may provide a display device able to improve the reflectivity and the reflective visibility of a display device without a polarizer.

Embodiments may provide a display device formed of a uni-material, in which materials for material components are simplified and unified, by using the same material for red and green color filters.

Embodiments may provide a display device able to provide high brightness and low power operation by designing an emission area such that light emitting elements have a long lifetime.

Embodiments may provide a display device including: a substrate including a first emission area, a second emission area, a third emission area; emitting elements disposed in the first to third emission areas, respectively; a first color filter, a second color filter, and a third color filter disposed over the emitting elements to correspond to the first to third emission areas, respectively; and a color filter composition including a dye not including a central metal in the molecule and a pigment, wherein each of the first color filter and the second color filter includes the color filter composition.

According to embodiments, the display device may reduce or prevent the occurrence of blemishes around the edges of the display device without a polarizer.

According to embodiments, the display device may improve the reflectivity and the reflective visibility of the display device without a polarizer.

According to embodiments, the display device formed of a uni-material, in which materials for material components are simplified and unified, may be provided by using the same material for red and green color filters.

According to embodiments, by designing an emission area such that light emitting elements have a long lifetime, the display device may provide high brightness and low power operation.

It is to be understood that both the foregoing general description and the following detailed description of the present disclosure are exemplary and explanatory and are intended to provide further explanation of the inventive concepts as claimed.

### DESCRIPTION OF THE SEVERAL VIEWS OF THE DRAWINGS

The above and other objectives, features, and advantages of the present disclosure will be more clearly understood from the following detailed description, taken in conjunction with the accompanying drawings, in which:

FIG. 1 illustrates a system configuration of a display device according to embodiments;

FIG. 2 illustrates an example equivalent circuit of a subpixel of the display panel according to embodiments;

FIG. 3 is an example plan diagram illustrating a portion of the display area of the display device according to embodiments;

FIG. 4 illustrates an example cross-sectional diagram cut along line I-I′ of FIG. 3;

FIG. 5 is another example plan diagram illustrating a portion of the display area of the display device according to embodiments;

FIG. 6 illustrates an example cross-sectional diagram cut along line I-I′ of FIG. 5;

FIG. 7 illustrates another example plan diagram of a portion of the display area in the display device according to embodiments;

FIG. 8 illustrates an example cross-sectional diagram cut along line I-I′ of FIG. 7;

FIG. 9 illustrates another example plan diagram of a portion of the display area in the display device according to embodiments;

FIG. 10 illustrates an example cross-sectional diagram cut along line I-I′ of FIG. 9;

FIGS. 11A and 11B respectively illustrate another example plan diagram of a portion of the display area in the display device according to embodiments;

FIG. 12 illustrates an example cross-sectional diagram cut along line I-I′ of FIGS. 11A and 11B;

FIG. 13 illustrates another example plan diagram of a portion of the display area in the display device according to embodiments;

FIG. 14 illustrates an example cross-sectional diagram cut along line I-I′ of FIG. 13;

FIG. 15 illustrates an example cross-sectional diagram cut along line I-I′ of FIGS. 11A and 11B;

FIG. 16 illustrates an example cross-sectional diagram cut along line I-I′ of FIGS. 11A and 11B;

FIGS. 17A and 17B illustrate transmissivity graphs of a display device according to a comparative example and a display device according to an example of the present disclosure;

FIG. 18 illustrates a graph comparing the reflective visibility of a display device according to a comparative example and a display device according to an example of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting” “made up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

In describing a position relationship, when a position relation between two parts is described as, for example, “on,” “over,” “under,” or “next,” one or more other parts may be disposed between the two parts unless a more limiting term, such as “just” or “direct (ly),” is used. In describing a time relationship, for example, when the temporal order is described as, “after,” “subsequent,” “next,” or “before,” a case that is not continuous may be included, unless a more limiting term, such as “just,” “immediate (ly),” or “direct (ly),” is used.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

Hereinafter, a variety of embodiments will be described in detail with reference to the accompanying drawings.

The term “halo” or “halogen,” as used in embodiments, includes fluorine (F), chlorine (Cl), bromine (Br), iodine (I), and the like unless otherwise specified.

The term “alkyl” or “alkyl group,” as used in embodiments, may mean a radical of a saturated aliphatic functional group, including a straight chain alkyl group, a branched chain alkyl group, a cycloalkyl (alicyclic) group, an alkyl-substituted cycloalkyl group, and a cycloalkyl-substituted alkyl group, having a carbon number of from 1 to 30, linked in a single bond, unless otherwise specified.

The term “alkenyl” or “alkynyl,” as used in embodiments, may mean a radical having double or triple bonds, including a straight or side chain group, and having a carbon number of from 2 to 30, unless otherwise specified.

The term “alkoxy group” or “alkyloxo group,” as used in embodiments, may mean an alkyl group to which an oxygen radical is attached and which has a carbon number of from 1 to 30, unless otherwise specified.

The term “aryl group,” as used in embodiments, may mean, but is not limited to, substituents each having a carbon number of from 6 to 50, unless otherwise indicated. In embodiments, an aryl group may include a monocyclic compound, a ring assembly, a fused polycyclic system, a spiro compound, and the like. For example, the aryl group may include, but is not limited to, a phenyl group, biphenyl, naphthyl, anthryl, indenyl, phenanthryl, triphenylenyl, pyrenyl, perylenyl, chrysenyl, naphthacenyl, fluoranthenyl, and the like. Naphthyl may include 1-naphthyl and 2-naphthyl, and anthryl may include 1-anthryl, 2-anthryl, and 9-anthryl.

The term “spiro compound,” as used in embodiments, means a compound having “a spiro union,” which refers to a union of two rings sharing only one atom. In this situation, the atoms shared by the two rings are referred to as “spiro atoms.” Such spiro compounds are referred to, for example, as “monospiro,” “dispiro,” and “trispiro” compounds depending on the number of spiro atoms included in the compound.

The term “heteroaryl group,” as used in embodiments, means, but is not limited to, an aromatic ring including one or more heteroatoms and having a carbon number of from 2 to 50. As used in embodiments, the term “heteroatom” may refer to N, O, S, P, or Si, unless otherwise specified, and the term “heterocyclic group” may mean a monocyclic compound, a ring assembly, a fused polycyclic system, a spiro compound, and the like each including heteroatoms.

The term “ring,” as used in embodiments, may include monocyclic rings and polycyclic rings, may include not only hydrocarbon rings but also hetero rings including at least one heteroatom, and may include aromatic rings and non-aromatic rings.

The term “ring assembly,” as used in embodiments, means a compound in which two or more rings (e.g., single rings or fused ring systems) are directly linked by a single or double bond. For example, in the aryl group, the ring assembly may be, but is not limited to, a biphenyl group, a terphenyl group, or the like.

The term “fused polycyclic system,” as used in embodiments, means a form of fused rings sharing at least two atoms. For example, in the aryl group, the fused polycyclic system may be, but is not limited to, a naphthalenyl group, a phenanthrenyl group, a fluorenyl group, or the like.

In addition, consecutively named prefixes may mean that substituents are listed in the order of the prefixes. For example, an arylalkoxy group may mean an alkoxy group substituted with an aryl group, an alkoxycarbonyl group may mean a carbonyl group substituted with an alkoxy group, and an arylcarbonyl alkenyl group may mean an alkenyl group substituted with an arylcarbonyl group. Here, the arylcarbonyl group may be a carbonyl group substituted with an aryl group.

Unless clearly stated otherwise, the term “substituted” in the term “substituted or non-substituted,” as used in embodiments, may mean substituted with one or more substituents selected from the group consisting of, but not limited to, deuterium, a halogen, a cyano group, an amino group, a nitro group, an amide group, a carbonyl group, a hydroxyl group, a sulfonyl group, a C₁-C₂₀ alkyl group, a C₂-C₂₀ alkenyl group, a C₂-C₂₀ alkynil group, a C₁-C₂₀ alkoxy group, a C₃-C₂₀ cycloalkyl group, a C₆-C₂₀ aryl group, a C₆-C₂₀ aryl group substituted with deuterium, a silane group, a boron group, a germanium group, and a C₂-C₂₀ heteroaryl group including at least one heteroatom selected from the group consisting of O, N, S, Si, or P.

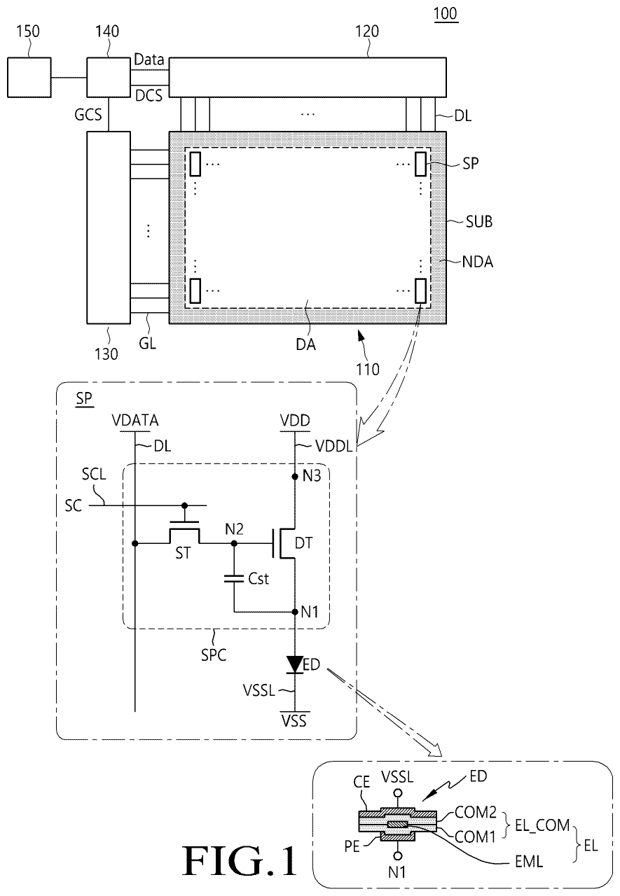

FIG. 1 illustrates a system configuration of a display device 100 according to embodiments.

Referring to FIG. 1, the display device 100 according to embodiments may include a display panel 110 and a driver circuit for driving the display panel 110.

The driver circuit may include a data driver circuit 120 and a gate driver circuit 130, and may further include a controller 140 to control the data driver circuit 120 and the gate driver circuit 130.

The display panel 110 may include a substrate SUB and signal lines, such as a plurality of data lines DL and a plurality of gate lines GL, disposed over the substrate SUB. The display panel 110 may include a plurality of subpixels SP connected to the plurality of data lines DL and the plurality of gate lines GL.

The display panel 110 may include a display area DA in which an image is displayed and a non-display area NDA in which no image is displayed. In the display panel 110, the display area DA may include a plurality of subpixels SP to display an image, and the non-display area NDA may include a pad part to which the driver circuits 120, 130, and 140 may be electrically connected or on which the driver circuits 120, 130, and 140 may be mounted and to which integrated circuits, printed circuits, or the like may be connected.

The data driver circuit 120 is a circuit for driving the plurality of data lines DL, and may supply data signals to the plurality of data lines DL.

The gate driver circuit 130 is a circuit for driving the plurality of gate lines GL, and may supply gate signals to the plurality of gate lines GL.

The controller 140 may supply the data driver circuit 120 with a data control signal DCS to control the timing of operation of the data driver circuit 120, and may supply the gate driver circuit 130 with a gate control signal GCS to control the timing of operation of the gate driver circuit 130.

The controller 140 may start scanning according to the timing set for respective frames, convert externally input image data (or video data) according to a data signal format used by the data driver circuit 120, supply the converted image data Data to the data driver circuit 120, and control data driving at appropriate times in response to the scanning.

The controller 140 receives a variety of timing signals, such as a vertical synchronization signal VSYNC, a horizontal synchronization signal HSYNC, an input data enable signal DE, and a clock signal CLK, as well as the input image data, from an external source 150 (e.g., a host system).

To control the data driver circuit 120 and the gate driver circuit 130, the controller 140 receives the timing signals, such as a vertical synchronization signal VSYNC, a horizontal synchronization signal HSYNC, an input data enable signal DE, and a clock signal CLK, generates various control signals DCS and GCS, and outputs the control signals DCS and GCS to the data driver circuit 120 and the gate driver circuit 130.

For example, the controller 140 outputs various gate control signals GCS, including a gate start pulse GSP, a gate shift clock GSC, a gate output enable signal GOE, and the like, to control the gate driver circuit 130.

In addition, the controller 140 outputs various data control signals DCS, including a source start pulse SSP, a source sampling clock SSC, a source output enable signal SOE, and the like, to control the data driver circuit 120.

The controller 140 may be implemented as a separate component from the data driver circuit 120, or may be integrated with the data driver circuit 120 to form an integrated circuit.

The data driver circuit 120 receives image data Data from the controller 140 and supplies a data voltage to the plurality of data lines DL to drive the plurality of data lines DL. Herein, the data driver circuit 120 is also referred to as a source driver circuit.

Such a data driver circuit 120 may include one or more source driver integrated circuits (SDICs).

Each of the source driver integrated circuits may include a shift register, a latch circuit, a digital to analog converter (DAC), an output buffer, and the like. In some situations, each of the source driver integrated circuits may further include an analog to digital converter (ADC).

For example, each source driver integrated circuit may be connected to the display panel 110 by a tape-automated bonding (TAB) method, connected to a bonding pad on the display panel 110 by a chip-on-glass (COG) method or a chip-on-panel (COP) method, or implemented by a chip-on-film (COF) method to be connected to the display panel 110.

The gate driver circuit 130 may output a gate signal of a turn-on level voltage or a gate signal of a turn-off level voltage under the control of the controller 140. The gate driver circuit 130 may sequentially supply a gate signal of the turn-on level voltage to the plurality of gate lines GL to sequentially drive the plurality of gate lines GL.

The gate driver circuit 130 may be connected to the display panel 110 by a tape-automated bonding (TAB) method, connected to a bonding pad on the display panel 110 by a chip-on-glass (COG) method or a chip-on-panel (COP) method, or connected to the display panel 110 by a chip-on-film (COF) method. In another example, the gate driver circuit 130 may be a gate-in-panel (GIP) circuit provided in the non-display area NDA of the display panel 110. The gate driver circuit 130 may be disposed over or connected to the substrate SUB. That is, the gate driver circuit 130 may be disposed in the non-display area NDA of the substrate SUB when the gate driver circuit 130 is a GIP circuit. The gate driver circuit 130 may be connected to the substrate SUB when the gate driver circuit 130 is a COG circuit, a COF circuit, or the like.

On the other hand, at least one driver circuit of the data driver circuit 120 or the gate driver circuit 130 may be disposed in the display area DA.

For example, the gate driver circuit 130 may be disposed in the display area DA. In this situation, the gate driver circuit 130 may be disposed throughout the entirety of the display area DA or only in a portion of the display area DA. The gate driver circuit 130 may be disposed so as not to overlap the subpixels SP, or may be disposed so as to overlap the entirety or a portion of the subpixels SP.

In another example, the data driver circuitry 120 may be disposed in the display area DA. In this situation, the data driver circuit 120 may be disposed throughout the entirety of the display area DA or may be disposed only in a portion of the display area DA. The data driver circuit 120 may be disposed so as not to overlap the subpixels SP, or may be disposed so as to overlap the entirety or a portion of the subpixels SP.

When a specific gate line GL is selected by the gate driver circuit 130, the data driver circuit 120 may convert the image data Data received from the controller 140 into an analog data voltage and supply the same to the plurality of data lines DL.

The data driver circuit 120 may be connected to one side (e.g., the top portion or the bottom portion) of the display panel 110. The data driver circuit 120 may be connected to both sides (e.g., the top portion or the bottom portion) of the display panel 110 or to two or more sides of the four sides of the display panel 110, depending on the driving method, the design of the display panel, or the like.

The gate driver circuit 130 may be connected to one side (e.g., the left portion or the right portion) of the display panel 110. The gate driver circuit 130 may be connected to both sides (e.g., the left portion and the right portion) of the display panel 110 or to two or more sides of the four sides of the display panel 110, depending on the driving method, the design of the display panel, or the like.

The controller 140 may be a timing controller used in general display technology, a control device including a timing controller and able to perform other control functions, a control device different from the timing controller, or a circuit within the control device. The controller 140 may be implemented as a variety of circuits or electronic components, such as an integrated circuit (IC), a field programmable gate array (FPGA), an application specific integrated circuit (ASIC), or a processor.

The controller 140 may be mounted on a printed circuit board (PCB), a flexible printed circuit (FPC), or the like, and may be electrically coupled to the data driver circuit 120 and the gate driver circuit 130 through the PCB, the FPC, or the like.

The controller 140 may transmit and receive signals to and from the data driver circuit 120 using one or more predetermined interfaces. Here, for example, the interfaces may include a low voltage differential signaling (LVDS) interface, an embedded clock point to point interface (EPI), a serial peripheral interface (SPI), and the like.

The controller 140 may include a storage medium such as one or more registers.

Referring to FIG. 1, in the display device 100 according to embodiments, each of the subpixels SP may include an emitting element ED and a subpixel circuit SPC for driving the emitting element ED.

The subpixel circuit SPC may include a plurality of pixel driving transistors for driving the emitting element ED and at least one capacitor. In the present disclosure, the subpixel circuit SPC may drive the emitting element ED by supplying a driving current to the emitting element ED at predetermined timing. The emitting element ED may be driven by the driving current to emit light.

The plurality of pixel driving transistors may include a driving transistor DRT to drive the emitting element ED and a scanning transistor SCT to be turned on or turned off based on a scanning signal SC.

The driving transistor DRT may supply a driving current to the emitting element ED.

The scanning transistor SCT may be configured to control the electrical state of a corresponding node (e.g., a second node N2) in the subpixel circuit SPC or to control the state or operation of the driving transistor DRT in the subpixel circuit SPC.

The at least one capacitor may include a storage capacitor Cst to maintain a constant voltage during a frame.

To drive the subpixel SP, a data signal VDATA which is an image signal, a scanning signal SC which is a gate signal, and the like may be applied to the subpixel SP. Further, a common driving voltage including a first common driving voltage VDD and a second common driving voltage VSS may be applied to the subpixel SP to drive the subpixel SP.

The emitting element ED may include a pixel electrode PE, an interlayer EL, and a common electrode CE. The interlayer EL may be disposed between the pixel electrode PE and the common electrode CE.

When the emitting element ED is an organic light-emitting device, the interlayer EL may include an emission layer EML and a common interlayer EL_COM. The common interlayer EL_COM may include a first common interlayer COM1 and a second common interlayer COM2. The first common interlayer COM1 may be disposed between the pixel electrode PE and the emission layer EML and include at least one layer (e.g., an organic film). The second common interlayer COM2 may be disposed between the emission layer EML and the common electrode CE and may include at least one layer (e.g., an organic film).

In an example, the emission layer EML may be disposed on each of the plurality of subpixels SP. In another example, the emission layer EML may be disposed in common across the plurality of subpixels SP. The common interlayer EL_COM may be disposed in common across the plurality of subpixels SP.

The emission layer EML may be disposed in respective emission areas, and the common interlayer EL_COM may be disposed in common across the plurality of emissive and a non-emission area.

The pixel electrode PE may be an electrode placed on each of the plurality of subpixels SP, and the common electrode CE may be an electrode common to the plurality of subpixel SP.

For example, the pixel electrode PE may be an anode and the common electrode CE may be a cathode. In another example, the pixel electrode PE may be a cathode and the common electrode CE may be an anode. In the example below, the pixel electrode PE is an anode and the common electrode CE is a cathode.

For example, the first common interlayer COM1 of the common interlayer EL_COM may include a hole injection layer HIL, a hole transfer layer HTL, and the like. The second common interlayer COM2 of the common interlayer EL_COM may include an electron transfer layer ETL, an electron injection layer EIL, and the like.

The hole injection layer may inject holes from the pixel electrode PE to the hole transfer layer, and the hole transfer layer may transport holes to the emission layer EML. The electron injection layer may inject electrons from the common electrode CE to the electron transfer layer, and the electron transfer layer may transport electrons to the emission layer EML.

For example, the common electrode CE may be electrically connected to a second common driving voltage line VSSL. A second common driving voltage VSS, which is a type of common driving voltage, may be applied to the common electrode CE through the second common driving voltage line VSSL. The pixel electrode PE may be electrically connected directly or indirectly (via other transistors) to the first node N1 of the driving transistor DRT of each of the subpixels SP. As used herein, the “second common driving voltage VSS” may also be referred to as the “base voltage VSS” and the “second common driving voltage line VSSL” may also be referred to as the “base voltage line VSSL.”

Each of the emitting elements ED may include an overlapping portion of the pixel electrode PE, the emission layer EML in the interlayer EL, and the common electrode CE. A predetermined emission area may be formed by each emitting element ED. For example, the emission area of each emitting element ED may include an overlapping portion of the pixel electrode PE, the emission layer EML in the interlayer EL, and the common electrode CE.

For example, the emitting element ED may be an organic light-emitting diode (OLED), an inorganic-based light-emitting diode (LED), a quantum dot light-emitting element, or the like. For example, when the emitting element ED is an organic light-emitting diode (OLED), the interlayer EL in the emitting element ED may include an organic film including an organic material.

The driving transistor DRT may be a driving transistor for supplying a driving current to the emitting element ED. The driving transistor DRT may be connected to the first common driving voltage line VDDL and the emitting element ED.

The driving transistor DRT may include a first node N1, a second node N2, and a third node N3. The first node N1 may be electrically connected to the emitting element ED, a data signal VDATA may be applied to the second node N2, and a first common driving voltage VDD from the first common driving voltage line VDDL may be applied to the third node N3.

In the driving transistor DRT, the second node N2 may be a gate node, the first node N1 may be a source node or a drain node, and the third node N3 may be a drain node or a source node. In the following, for the sake of brevity, a situation in which the second node N2 is a gate node, the first node N1 is a source node, and the third node N3 is a drain node in the driving transistor DRT is taken as an example.

The scanning transistor SCT included in the subpixel circuit SPC illustrated in FIG. 1 may be a switching transistor for transferring a data signal VDATA, which is an image signal, to the second node N2, which is the gate node of the driving transistor DRT.

The scanning transistor SCT may be controlled to turn on and off by a scanning signal SC, which is a gate signal applied through the scanning signal line SCL, which is a type of gate line GL, to control an electrical connection between the second node N2 of the driving transistor DRT and the data line DL. The drain electrode or the source electrode of the scanning transistor SCT may be electrically connected to the data line DL, the source electrode or the drain electrode of the scanning transistor SCT may be electrically connected to the second node N2 of the driving transistor DRT, and the gate electrode of the scanning transistor SCT may be electrically connected to the scanning signal line SCL.

The storage capacitor Cst may be electrically connected to the first node N1 and the second node N2 of the driving transistor DRT. The storage capacitor Cst may include a first capacitor electrode electrically connected to the first node N1 of the driving transistor DRT or corresponding to the first node N1 of the driving transistor DRT and a second capacitor electrode electrically connected to the second node N2 of the driving transistor DRT or corresponding to the second node N2 of the driving transistor DRT.

The storage capacitor Cst may be an external capacitor intentionally designed to be provided outside the driving transistor DRT, rather than a parasitic capacitor (e.g., Cgs, Cgd), which is an internal capacitor present between the first node N1 and the second node N2 of the driving transistor DRT.

Each of the driving transistor DRT and the scanning transistor SCT may be an n-type transistor or a p-type transistor.

The display panel 110 may have a top emission structure or a bottom emission structure.

When the display panel 110 has the top emission structure, at least a portion of the subpixel circuit SPC may overlap at least a portion of the emitting element ED in a vertical direction. Accordingly, the area of the emission area may be increased and the aperture ratio may be increased.

When the display panel 110 has the bottom emission structure, the subpixel circuit SPC may not overlap the emitting element ED in the vertical direction.

The subpixel circuit SPC may have a 2TIC structure including two transistors DRT and SCT and one capacitor Cst as shown in FIG. 1, and in some situations, may include one or more transistors and/or one or more capacitors.

Depending on the structure of the subpixel circuit SPC, the type and number of gate signals supplied to and gate lines connected to the subpixel SP may vary. Further, depending on the structure of the subpixel circuit SPC, the type and number of common driving voltages supplied to the subpixel SP may vary.

Because the circuit elements in the respective subpixels SP (in particular, the emitting element ED implemented as an organic light-emitting diode (OLED) including an organic material) are susceptible to external moisture or oxygen, an encapsulation layer may be disposed on the display panel 110 to prevent external moisture or oxygen from penetrating the circuit elements (particularly, the emitting element ED). The encapsulation layer may be configured in various forms to prevent the emitting element ED from coming into contact with moisture or oxygen.

The display device 100 according to embodiments may be a display device in which the display panel 110 does not emit light by itself. For example, the display device 100 according to embodiments may be a liquid crystal display (LCD) including a backlight unit.

In another example, the display device 100 according to embodiments may be a self-emitting display device in which the display panel 110 is able to emit light by itself. For example, the display device 100 according to embodiments may be one of an organic light-emitting diode (OLED) display, a quantum dot display, a micro light-emitting diode (Micro LED) display, or the like.

When the display device 100 according to embodiments is an organic light-emitting diode display device, each of the subpixels SP may include an organic light-emitting diode that emits light by itself as an emitting element. When the display device 100 according to embodiments is a quantum dot display device, each of the subpixels SP may include an emitting element implemented as a quantum dot that is a self-emitting semiconductor crystal. When the display device 100 according to embodiments is a micro light-emitting diode display device, each of the subpixels SP may include an emitting element implemented as a micro light-emitting diode that is a self-emitting semiconductor crystal made of a mineral-based material.

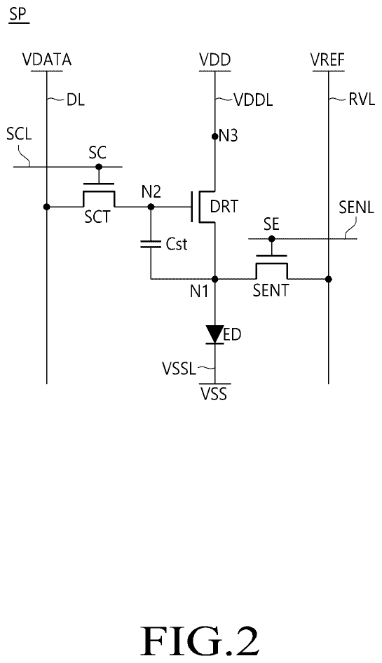

FIG. 2 illustrates an example equivalent circuit of a subpixel of the display panel 110 according to embodiments. In the following description, the features the same as or similar to those described with reference to FIG. 1 are omitted or briefly described.

Referring to FIG. 2, each of a plurality of subpixels SP disposed on the display panel 110 of the display device 100 according to embodiments may further include a sensing transistor SENT, compared to the subpixel SP shown in FIG. 1.

Referring to FIG. 2, the sensing transistor SENT may be controlled by a sensing signal SE, which is a type of gate signal, and may be connected to the first node N1 of the driving transistor DRT and a reference voltage line RVL. In other words, the sensing transistor SENT may be turned on or off by the sensing signal SE supplied from the sensing signal line SENL, which is another type of gate line GL, and control the connection between the reference voltage line RVL and the first node N1 of the driving transistor DRT.

The sensing transistor SENT may be turned on by the sensing signal SE having a turn-on level voltage and transfer a reference voltage VREF supplied from the reference voltage line RVL to the first node N1 of the driving transistor DRT.

In addition, the sensing transistor SENT may be turned on by the sensing signal SE having a turn-on level voltage and transfer the voltage of the first node N1 of the driving transistor DRT to the reference voltage line RVL.

Here, when the sensing transistor SENT is an n-type transistor, the turn-on level voltage of the sensing signal SE may be a high-level voltage. When the sensing transistor SENT is a p-type transistor, the turn-on level voltage of the sensing signal SE may be a low-level voltage.

The function of the sensing transistor SENT to transfer the voltage of the first node N1 of the driving transistor DRT to the reference voltage line RVL may be used when driving to sense characteristic values of the subpixel SP. In this situation, the voltage transferred to the reference voltage line RVL may be a voltage for calculating the characteristic values of the subpixel SP or a voltage reflecting the characteristic values of the subpixel SP.

In the present disclosure, the characteristic values of the subpixel SP may be characteristic values of the driving transistor DRT or the emitting element ED. For example, the characteristic values of the driving transistor DRT may include the threshold voltage and the mobility of the driving transistor DRT. The characteristic values of the emitting element ED may include the threshold voltage of the emitting element ED.

The sensing transistor SENT may be an n-type transistor or a p-type transistor. In the present disclosure, for the sake of brevity, the sensing transistor SENT is assumed to be an n-type transistor.

The scanning signal line SCL and the sensing signal line SENL may be different gate lines GL. In this situation, the scanning signal SC and the sensing signal SE may be separate gate signals, and the on-off timing of the scanning transistor SCT and the on-off timing of the sensing transistor SENT in one subpixel SP may be independent. That is, the on-off timing of the scanning transistor SCT and the on-off timing of the sensing transistor SENT in one subpixel SP may be the same or different.

In contrast, the scanning signal line SCL and the sensing signal line SENL may be the same gate line GL. That is, the gate node of the scanning transistor SCT and the gate node of the sensing transistor SENT in one subpixel SP may be connected to a single gate line GL. In this situation, the scanning signal SC and the sensing signal SE may be the same gate signal, and the on-off timing of the scanning transistor SCT and the on-off timing of the sensing transistor SENT in the one subpixel SP may be the same.

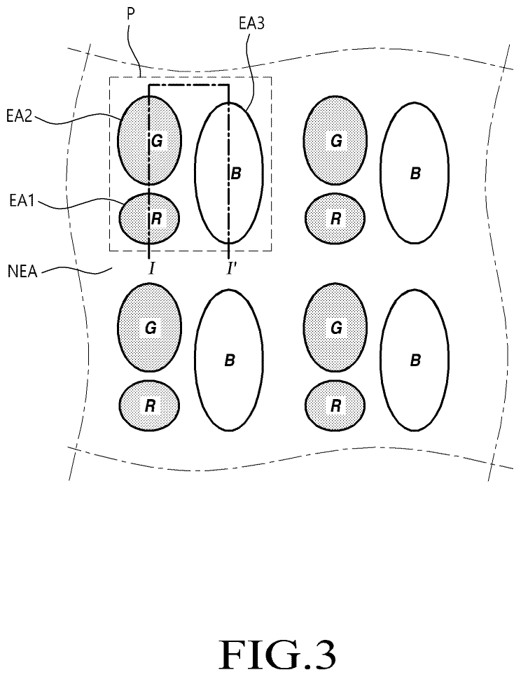

FIG. 3 is an example plan diagram illustrating a portion of the display area of the display device 100 according to embodiments. In the following description, the features the same as or similar to those described with reference to FIGS. 1 and 2 are omitted or briefly described.

Referring to FIG. 3, the display device 100 according to embodiments may include a plurality of emission areas EA1, EA2, and EA3 and a non-emission area NEA surrounding the plurality of emission areas EA1, EA2, and EA3.

For example, the display device 100 according to embodiments may include a first emission area EA1, a second emission area EA2, and a third emission area EA3 to emit different colors of light.

The first emission area EA1 may be a red emission area, the second emission area EA2 may be a green emission area, and the third emission area EA3 may be a blue emission area.

In addition, FIG. 3 illustrates a structure in which the first to third emission areas EA1, EA2, and EA3 that emit different colors of light are provided in the display area of the display device 100, but embodiments may also include a structure in which the display area has four or more emission areas that emit different colors of light.

Referring to FIG. 3, the planar area of at least one emission area of the first to third emission areas EA1, EA2, and EA3 may be different from the planar area of the remaining emission areas.

For example, the area of the third emission area EA3 may be larger than the area of the first and second emission areas EA1 and EA2. Further, the area of the second emission area EA2 may be larger than the area of the first emission area EA1.

In this manner, by designing the emission areas EA1, EA2, and EA3 of different colors to have different areas, the different lifetimes, different transmissivity characteristics, and different reflectivity characteristics of the emitting elements disposed in the respective emission areas EA1, EA2, and EA3 may be taken into account to achieve optimal efficiency.

Specifically, the lifetime of the emitting element that emits blue light (or blue emitting element) may be shorter than the lifetimes of the emitting element that emits red light (or red emitting element) and the emitting element that emits green light (or green emitting element). To compensate for this, the area of the blue emission area may be larger than each of the area of the red emission area and the area of the green emission area.

Embodiments may include a color filter disposed over the substrate to reduce the external light reflectivity.

In this situation, in general, a red color filter may be disposed in the area corresponding to the red emission area, a green color filter may be disposed in the area corresponding to the green emission area, and a blue color filter may be disposed in the area corresponding to the blue emission area.

In such a structure, the green emitting element has a longer lifetime than the blue emitting element, but when the area of the green emission area in which the green color filter is disposed is reduced, the transmission efficiency of light may be reduced, which is problematic. However, when the area of the green emission area is increased in consideration of the transmissivity efficiency, the reflective visibility of the display device may have a greenish characteristic, which is a green color tone.

On the other hand, color filters are generally colored with colorants, such as dyes that are soluble in solvents or pigments that are insoluble in solvents and exist as dispersed particles. In particular, phthalocyanine-based compounds are generally used as green pigments for green color filters.

Phthalocyanine-based compounds used as green pigments have a structure in which a central metal (e.g., copper (Cu)) is bonded to a molecule in the form of a metal complex. In high temperature and/or high humidity operating environments, when light is directed onto a green color filter in which a phthalocyanine-based compound is used, photocatalytic electron transfer may occur and cause the central metal and water in the molecule of the phthalocyanine-based compound to undergo an oxidation-reduction reaction to generate oxygen gas. In this situation, when hydration is interrupted, hydrogen bonding of intermolecular water in the phthalocyanine compound may form, thereby resulting in a new absorption peak within the green transmission wavelength. In addition, upon rehydration, the oxidation-reduction reaction may be reactivated and produce oxygen gas.

Externally penetrated moisture may be trapped by the encapsulation layer under the color filter and the cover window over the color filter, and may be more persistent in the central portion of the display area. As a result, a luminance difference may occur between the central portion and the edges of the display area due to light/water reactions of the central metal in the molecules of the phthalocyanine-based compound used as a green pigment. The luminance difference between the central portion of the display area and the edges of the display area may cause blemishes around the edges (hereinafter, also referred to as “edge blemishes”) of the display area.

In the display device 100 according to embodiments, reflective visibility may be improved and edge blemishes may be reduced or prevented by applying the color filter composition including a dye and a pigment to the color filters disposed on the red emitting element and the green emitting element.

Although not shown in FIG. 3, the non-emission area NEA of the display device 100 may include a plurality of signal lines and overlap circuits desirable to drive the emitting elements disposed in the plurality of emission areas EA1, EA2, and EA3.

In addition, the circuits for driving the plurality of emitting elements of the display device 100 according to embodiments may overlap the plurality of emission areas EA1, EA2, and EA3 as well as the non-emission area NEA.

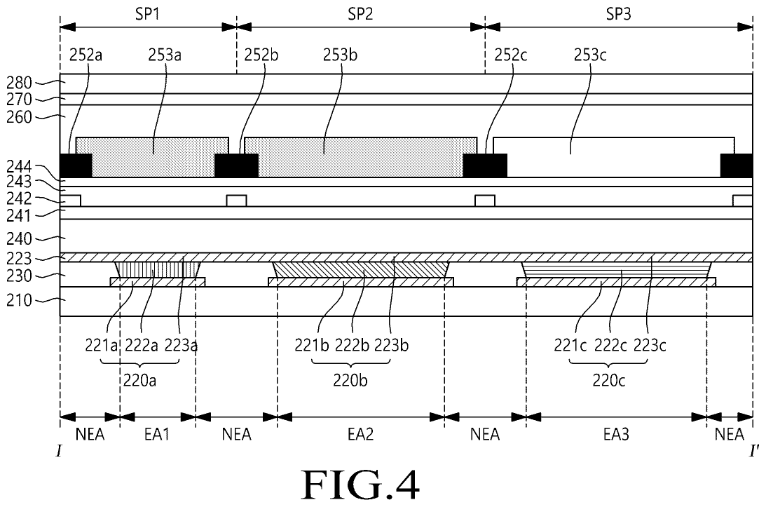

Next, the structure of the display device 100 according to embodiments will be discussed in detail as follows with reference to FIG. 4. In the following description, the features the same as or similar to those described with reference to FIGS. 1 to 3 are omitted or briefly described.

FIG. 4 illustrates an example cross-sectional diagram cut along line I-I′ of FIG. 3.

Referring to FIG. 4, the display device 100 according to embodiments may include a plurality of subpixels SP1, SP2, and SP3 and a plurality of emission areas EA1, EA2, and EA3 provided in a display area DA.

The display device 100 according to embodiments may include a first subpixel SP1, a second subpixel SP2, and a third subpixel SP3. The first subpixel SP1 may include a first emission area EA1, the second subpixel SP2 may include a second emission area EA2, and the third subpixel SP3 may include a third emission area EA3.

The first emission area EA1, the second emission area EA2, and the third emission area EA3 may be areas that emit different colors of light. For example, the first emission area EA1 may be an area where red (R) light is emitted, the second emission area EA2 may be an area where green (G) light is emitted, and the third emission area EA3 may be an area where blue (B) light is emitted, but embodiments are not limited thereto.

In this situation, light emitted from a first emission layer 222a of a first emitting element 220a disposed in the first emission area EA1, light emitted from a second emission layer 222b of a second emitting element 220b disposed in the second emission area EA2, and light emitted from a third emission layer 222c of a third emitting element 220c disposed in the third emission area EA3 may have different colors. Red (R) light may be emitted from the first emission layer 222a, green (G) light may be emitted from the second emission layer 222b, and blue (B) light may be emitted from the third emission layer 222c, but embodiments are not limited thereto.

Referring to FIG. 4, the display device 100 according to embodiments may include a substrate 210, the emitting elements 220a, 220b, and 220c, an encapsulation layer 240, touch electrodes 242, a light blocking layer 252a, 252b, and 252c, and color filters 253a, 253b, and 253c.

The substrate 210 may include an insulating material. The substrate 210 may be a glass substrate, a resin, a flexible polymer film or a plastic substrate, or the like. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto. For example, the substrate 210 may be a polymide (PI) substrate. The substrate 210 may have a single-layer structure or a multi-layer structure.

A thin film transistor layer (not shown) may be disposed over the substrate 210. The thin film transistor layer (not shown) may be a layer on which thin film transistors for driving the emitting elements 220a, 220b, and 220c are located. Each of the thin film transistors may include an active layer, a gate electrode, a source electrode, and a drain electrode.

The emitting elements 220a, 220b, and 220c may be disposed over the substrate 210. The emitting elements 220a, 220b, and 220c may be located over the thin film transistor layer (not shown) and electrically connected to the thin film transistors of the thin film transistor layer (not shown) to be driven by the same.

The emitting element may include a first electrode, an emission layer, and a second electrode. For example, the first emitting element 220a may include a first electrode 221a, a first emission layer 222a, and a second electrode 223a, the second emitting element 220b may include a first electrode 221b, a second emission layer 222b, and a second electrode 223b, and the third emitting element 220c may include a first electrode 221c, a third emission layer 222c, and a second electrode 223c.

First electrodes 221a, 221b, and 221c of the emitting elements 220a, 220b, and 220c may be disposed over the substrate 210. The first electrodes 221a, 221b, and 221c may be electrically connected to source electrodes or drain electrodes of the thin film transistors located in the thin film transistor layer (not shown).

The first electrodes 221a, 221b, and 221c are respectively shown in FIG. 4 as having a single-layer structure, but embodiments are not limited thereto. For example, the first electrodes 221a, 221b, and 221c may respectively have a multi-layer structure comprised of two or more layers.

Each of the first electrodes 221a, 221b, and 221c may include a reflective electrode.

For example, when each of the first electrodes 221a, 221b, and 221c has a single-layer structure, the first electrodes 221a, 221b, and 221c may be reflective electrodes including a reflective conductive material.

For example, when the first electrodes 221a, 221b, and 221c respectively have a multilayer structure, at least one layer may be a reflective electrode including a reflective conductive material. In addition, the remaining layer(s) other than a reflective electrode may be a layer of transparent or translucent conductive material.

A bank 230 may be disposed over the substrate 210.

The bank 230 may be disposed to overlap a portion of the top surfaces of the first electrodes 221a, 221b, and 221c. The bank 230 may be disposed to expose a portion of the top surfaces of the first electrodes 221a, 221b, and 221c. The bank 230 may include open areas corresponding to the emitting elements 220a, 220b, and 220c.

The bank 230 may define the emission areas EA1, EA2, and EA3 and the non-emission area NEA in the display area DA of the display device 100. For example, a portion of the display area DA in which the bank 230 is disposed may be the non-emission area NEA, and a portion of the display area DA in which the bank 230 is not disposed may be the emission areas EA1, EA2, and EA3.

The bank 230 may include a black component. For example, the bank 230 may be made of an opaque colored organic material. The bank 230 may be a black bank made of a black colored organic material, but the present disclosure is not limited thereto.

The emission layers 222a, 222b, and 222c of the emitting elements 220a, 220b, and 220c may be disposed over the first electrodes 221a, 221b, and 221c.

The emission layers 222a, 222b, and 222c may be disposed on the top surfaces of the first electrodes 221a, 221b, and 221c exposed through the bank 230.

The emission layers 222a, 222b, and 222c are respectively shown in FIG. 4 as having a single-layer structure, but embodiments are not limited thereto. Each of the emission layers 222a, 222b, and 222c may include a plurality of organic material layers.

These emission layers 222a, 222b, and 222c may emit at least one color selected from red (R), green (G), and blue (B). However, embodiments are not limited thereto.

The second electrodes 223 (223a, 223b, and 223c) of the emitting elements 220a, 220b, and 220c may be disposed over the substrate 210 on which the emission layers 222a, 222b, and 222c are disposed.

The second electrodes 223a, 223b, and 223c may include a transparent conductive material or a semi-permeable material.

The second electrodes 223a, 223b, and 223c are respectively shown in FIG. 4 as having a single-layer structure, but embodiments are not limited thereto. The second electrodes 223a, 223b, and 223c may respectively may a multi-layer structure comprised of two or more layers.

The encapsulation layer 240 may be disposed over the second electrodes 223a, 223b, and 223c.

The encapsulation layer 240 is shown in FIG. 4 as having a single-layer structure, but embodiments are not limited thereto.

For example, the encapsulation layer 240 may include a first encapsulation layer disposed over the second electrodes 223a, 223b, and 223c, a second encapsulation layer disposed over the first encapsulation layer, and a third encapsulation layer disposed over the second encapsulation layer. Here, the first and third encapsulation layers may include an inorganic insulating material, and the second encapsulation layer may include an organic insulating material.

Such an encapsulation layer 240 may prevent moisture and oxygen from penetrating the emitting elements 220a, 220b, and 220c.

A touch sensor part may be disposed over the encapsulation layer 240.

The touch sensor part may include the touch electrodes 242, and may further include insulating film components such as a sensor buffer layer 241, a sensor interlayer insulating layer 243, and a sensor passivation layer 244.

The sensor buffer layer 241 may be disposed over the encapsulation layer 240. The touch electrodes 242 may be disposed over the sensor buffer layer 241, and the sensor interlayer insulating layer 243 may be disposed over the touch electrodes 242.

The sensor buffer layer 241 and the sensor interlayer insulating layer 243 may be disposed to extend not only to the display area DA of the display device 100, but also to the non-display area NDA.

The touch electrodes 242 may include touch sensor metals and bridge metals.

The touch sensor metals may form a single touch electrode 242 (or a single touch electrode line), and may be arranged in the shape of a mesh and electrically connected to each other. Some touch sensor metals and other touch sensor metals may be electrically connected through bridge metals to form a single touch electrode 242 (or a single touch electrode line).

The touch electrodes 242 may be arranged so as not to overlap the plurality of emission areas EA1, EA2, and EA3.

That is, the touch electrodes 242 may be disposed in an area overlapping the bank 230.

The sensor interlayer insulating layer 243 may be disposed over the touch electrodes 242.

The sensor passivation layer 244 may be disposed over the sensor interlayer insulating layer 243.

The light blocking layer 252a, 252b, and 252c having open areas may be disposed over the sensor passivation layer 244.

Referring to FIG. 4, the light blocking layer 252a, 252b, and 252c may overlap the non-emission area NEA. For example, the light blocking layer 252a, 252b, and 252c may be disposed to overlap the bank 230. The light blocking layer 252a, 252b, and 252c may be disposed to overlap the touch electrodes 242. The light blocking layer 252a, 252b, and 252c may be disposed to overlap the bank 230 and the touch electrodes 242. The open areas of the light blocking layer 252a, 252b, and 252c may overlap the first to third emission areas EA1, EA2, and EA3.

The light blocking layer 252a, 252b, and 252c may include a black component. For example, the light blocking layer 252a, 252b, and 252c may be made of an opaque colored organic material and may have a single-layer structure or a multi-layer structure.

The color filters 253a, 253b, 253c may be disposed in open areas of the light blocking layer 252a, 252b, and 252c.

Referring to FIG. 4, the first color filter 253a may overlap the first emission area EA1 and may also overlap a portion of the non-emission area NEA surrounding the first emission area EA1. The second color filter 253b may overlap the second emission area EA2 and may also may overlap a portion of the non-emission area NEA surrounding the second emission area EA2. The third color filter 253c may overlap the third emission area EA3 and may also overlap a portion of the non-emission area NEA surrounding the third emission area EA3.

The first emitting element 220a disposed in the first emission area EA1 may emit red (R) light. The second emitting element 220b disposed in the second emission area EA2 may emit green (G) light. The third emitting element 220c disposed in the third emission area EA3 may emit blue (B) light.

As described above, increasing the second emission area EA2 from which green (G) light is emitted may cause the reflective visibility of the display device to exhibit a greenish characteristic, which is problematic. In addition, phthalocyanine-based compounds used as green pigments in green color filters may experience a luminance difference between the central portion of the display area and the edges of the display area due to light/water reactions of the central metal in the molecule, thereby resulting in edge blemishes of the display area.

In the display device 100 according to embodiments, the reflective visibility of the display may be improved and the edge blemishes of the display device may be prevented or reduced by applying a color filter composition including a dye and a pigment to the color filters disposed on the red emitting element and the green emitting element, respectively.

The first color filter 253a and the second color filter 253b may include a color filter composition. That is, the first color filter 253a disposed over the first emitting element 220a emitting red (R) light and the second color filter 253b disposed over the second emitting element 220b emitting green (R) light may include the same color filter composition.

The first color filter 253a and the second color filter 253b including the color filter composition may have a first peak absorption wavelength and a second peak absorption wavelength.

The first color filter 253a and the second color filter 253b may have the first peak absorption wavelength in a range between 430 nm and 480 nm. The first color filter 253a and the second color filter 253b may have the second peak absorption wavelength in a range between 580 nm and 600 nm.

The first color filter 253a and the second color filter 253b may have the first peak absorption wavelength in the range between 430 nm and 480 nm and the second peak absorption wavelength in the range between 580 nm and 600 nm.

The first color filter 253a and the second color filter 253b may have a transmissivity of 10% or less of an absorption peak in the range between 430 nm and 480 nm. The first color filter 253a and the second color filter 253b may have a transmissivity of 10% or less of an absorption peak in the range between 580 nm and 600 nm.

The first color filter 253a and the second color filter 253b may have a transmissivity of 10% or less of an absorption peak in the range between 430 nm and 480 nm and a transmissivity of 10% or less of an absorption peak in the range between 580 nm and 600 nm.

The first color filter 253a and the second color filter 253b may have a first absorption peak wavelength in the range between 430 nm and 480 nm, and the transmissivity of the absorption peak in the range of the first peak absorption wavelength may be 10% or less.

The first color filter 253a and the second color filter 253b may have a second absorption peak wavelength in a range between 580 nm and 600 nm, and the transmissivity of the absorption peak in the range of the second peak absorption wavelength may be 10% or less.

The color filter composition may include a dye and a pigment.

The color filter composition may include, by weight, more than 0% but more than 20% of the dye of the sum of the dye and the pigment. When the color filter composition includes, by weight, less than or equal to 0% of the dye, i.e., no dye, the color filter may not have a second peak absorption wavelength in the range between 580 nm and 600 nm, and blemishes may occur around the edges. Including more than 20% by weight of the dye may increase power consumption.

The dye included in the color filter composition may be represented by Formula 1 below.

Formula 1 will be described below.

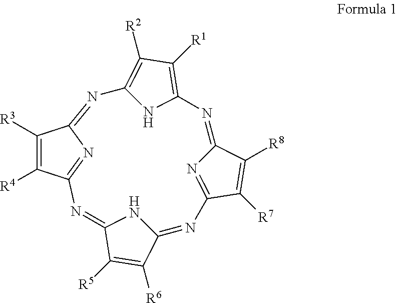

Formula 1 is of the porphyrin family, wherein R¹ to R⁸ may be selected independently of each other from the group consisting of hydrogen, a halogen atom, a cyano group, an amino group, a nitro group, an amide group, a carbonyl group, a hydroxyl group, a sulfonyl group, a C₁-C₃₀ alkyl group, a C₂-C₃₀ alkenyl group, a C₂-C₃₀ alkynyl group, a C₁-C₃₀ alkoxy group, a C₆-C₅₀ aryl group, and a C₂-C₅₀ heteroaryl group.

In R¹ to R⁸ of Formula 1, the alkyl, alkenyl, alkynyl, alkoxy, aryl, and heteroaryl groups, each independently, may be further substituted with one or more substituents selected from the group consisting of deuterium, tritium, a nitro group, a halogen, a cyano group, an amino group, a C₁-C₂₀ alkyl group, a C₂-C₂₀ alkenyl group, a C₂-C₂₀ alkynyl group, a C₁-C₂₀ alkoxy group, a C₆-C₂₀ aryl group, a C₆-C₂₀ aryl group substituted with deuterium, and a C₂-C₂₀ heteroaryl group.

In Formula 1, the four central nitrogens (N) may not be metal-bonded. That is, the dye represented by Formula 1 according to embodiments does not include a central metal in the molecule. By not including a central metal in the molecule, the light/water reaction does not occur, thereby resulting in uniform luminance between the central portion and the edges of the display area. Accordingly, the occurrence of edge blemishes of the display area may be reduced or prevented.

The display device 100 according to embodiments may improve reflective visibility and reduce edge blemishes of the display device by applying the color filter composition including the dye represented by Formula 1 and a pigment to the first color filter 253a and the second color filter 253b disposed on the red and green emitting elements 220a and 220b.

The pigment included in the color filter composition may be a yellow pigment. For example, the yellow pigment may be at least one selected from the group consisting of C.I. Pigment Yellow 11, 13, 24, 55, 108, 109, 110, 119, 138, 139, 150, 151, 154, 167, 168, 180, 185, and 231.

The display device 100 according to embodiments may improve reflective visibility and reduce or prevent edge blemishes of the display device by applying the color filter composition including the dye represented by Formula 1 and a yellow pigment to the first color filter 253a and the second color filter 253b disposed on the red and green emitting elements 220a and 220b.

The pigment included in the color filter composition may be represented by Formula 2 below.

Formula 2 will be described below.

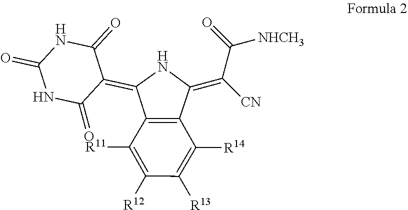

Formula 2 is of the isoindoline family, wherein R¹¹ to R¹⁴ may be selected independently of each other from the group consisting of hydrogen, a halogen atom, a cyano group, an amino group, a nitro group, an amide group, a carbonyl group, a hydroxyl group, a sulfonyl group, a C₁-C₃₀ alkyl group, a C₂-C₃₀ alkenyl group, a C₂-C₃₀ alkynyl group, a C₁-C₃₀ alkoxy group, a C₆-C₅₀ aryl group, and a C₂-C₅₀ heteroaryl group.

In R¹¹ to R¹⁴ of Formula 2, the alkyl, alkenyl, alkynyl, alkoxy, aryl, and heteroaryl groups, each independently, may be further substituted with one or more substituents selected from the group consisting of deuterium, tritium, a nitro group, a halogen, a cyano group, an amino group, a C₁-C₂₀ alkyl group, a C₂-C₂₀ alkenyl group, a C₂-C₂₀ alkynyl group, a C₁-C₂₀ alkoxy group, a C₆-C₂₀ aryl group, a C₆-C₂₀ aryl group substituted with deuterium, and a C₂-C₂₀ heteroaryl group.

The display device 100 according to embodiments may improve reflective visibility and reduce or prevent edge blemishes of the display device by applying the color filter composition including the dye represented by Formula 1 and the pigment represented by Formula 2 to the first color filter 253a and the second color filter 253b disposed on the red and green emitting elements 220a and 220b.

A passivation layer 260 may be disposed over the color filters 253a, 253b, and 253c. The passivation layer 260 may be disposed over the color filters 253a, 253b, and 253c and the light blocking layer 252a, 252b, and 252c, and may extend not only to the display area DA, but also to the non-display area NDA of the display device 100.

An adhesive layer 270 and a cover window 280 may be disposed over the color filters 253a, 253b, and 253c. The adhesive layer 270 and the cover window 280 may be disposed over the passivation layer 260.

The adhesive layer 270 may be a transparent adhesive layer 270. In this situation, the adhesive layer 270 may be an optically clear adhesive (OCA) or an optically clear resin (OCR).

In addition, the adhesive layer 270 may include a color, and may include a black color. When the adhesive layer 270 has a black color, the OCA or the OCR may have insulating black colored particles dispersed therein. The black colored adhesive layer 270 may serve to reduce the external light reflectivity of the display device 100 that does not include a polarizer.

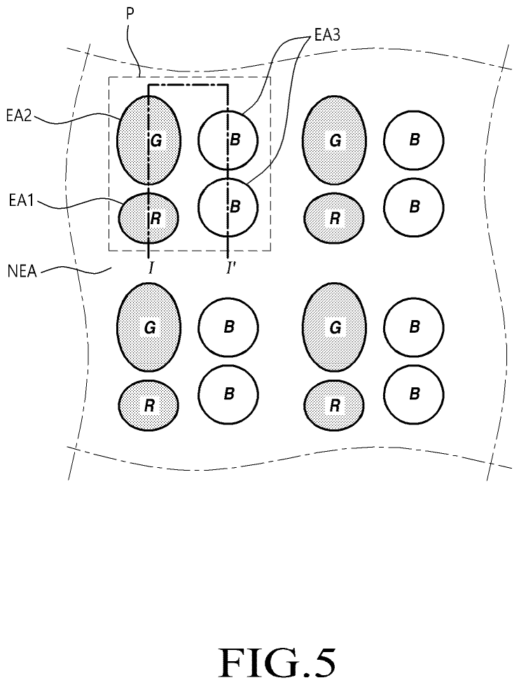

FIG. 5 is another example plan diagram illustrating a portion of the display area of the display device 100 according to embodiments. In the following description, the features the same as or similar to those described with reference to FIGS. 1 to 4 are omitted or briefly described.

Referring to FIG. 5, the display device 100 according to embodiments may include a plurality of emission areas EA1, EA2, and EA3 and a non-emission area NEA surrounding the plurality of emission areas EA1, EA2, and EA3.

The first emission area EA1 may be a red emission area, the second emission area EA2 may be a green emission area, and the third emission area EA3 may be a blue emission area.

Referring to FIG. 5, the third emission area EA3 may be divided into two emission areas. For example, a third color filter disposed in an area corresponding to the third emission area EA3 may be divided into two sub-color filters. The color filters and the sub-color filters to be described hereinafter may respectively have a circular or polygonal shape.

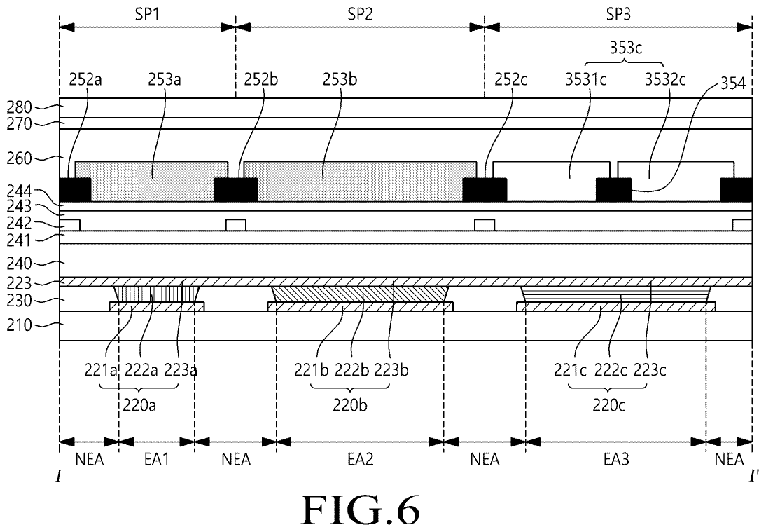

FIG. 6 illustrates an example cross-sectional diagram cut along line I-I′ of FIG. 5. In the following description, the features the same as or similar to those described with reference to FIGS. 1 to 5 are omitted or briefly described.

Referring to FIG. 6, the third subpixel SP3 may include a third color filter 353c divided into two third sub-color filters 3531c and 3532c.

Referring to FIG. 6, a light blocking layer 252a, 252b, and 252c and a third sub-light blocking layer 354 may be disposed over the sensor passivation layer 244.

The light blocking layer 252a, 252b, and 252c and the third sub-light blocking layer 354 may include open areas. The third sub-color filters 3531c and 3532c may be disposed in the two open areas of the third subpixel SP3 area.

Referring to FIG. 6, the third sub-light blocking layer 354 may be disposed to overlap the third emitting element 220c. The width of the third sub-light blocking layer 354 may be smaller than the width of the light blocking layer 252a, 252b, and 252c.

Referring to FIG. 6, the third color filter 353c may include two third sub-color filters 3531c and 3532c. The third sub-color filters 3531c and 3532c may overlap the third emission area EA3 and may also overlap a portion of the non-emission area NEA surrounding the third emission area EA3.

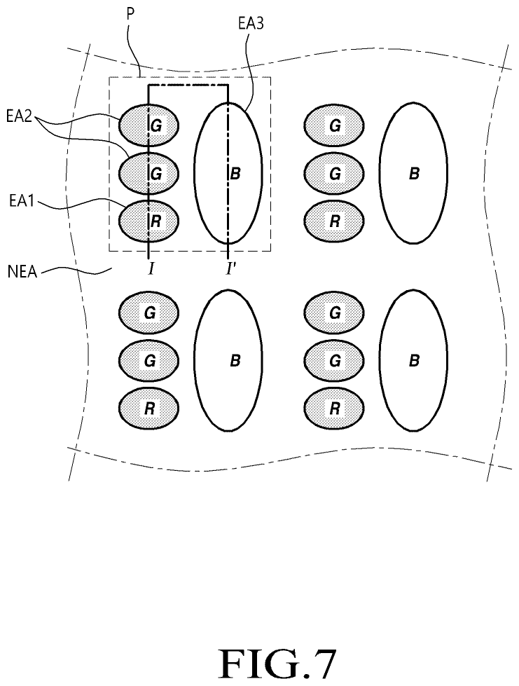

FIG. 7 illustrates another example plan diagram of a portion of the display area in the display device according to embodiments. In the following description, the features the same as or similar to those described with reference to FIGS. 1 to 6 are omitted or briefly described.

Referring to FIG. 7, the display device 100 according to embodiments may include a plurality of emission areas EA1, EA2, and EA3 and a non-emission area NEA surrounding the plurality of emission areas EA1, EA2, and EA3.

The first emission area EA1 may be a red emission area, the second emission area EA2 may be a green emission area, and the third emission area EA3 may be a blue emission area.

Referring to FIG. 7, the second emission area EA2 may be divided into two emission areas. For example, a second color filter disposed in an area corresponding to the second emission area EA2 may be divided into two sub-color filters.

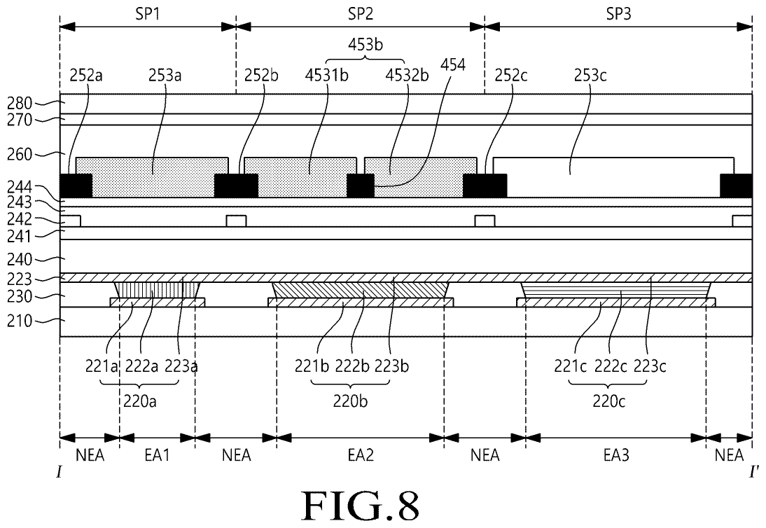

FIG. 8 illustrates an example cross-sectional diagram cut along line I-I′ of FIG. 7. In the following description, the features the same as or similar to those described with reference to FIGS. 1 to 7 are omitted or briefly described.

Referring to FIG. 8, the second subpixel SP2 may include a second color filter 453b divided into two second sub-color filters 4531b and 4532b.

Referring to FIG. 8, a light blocking layer 252a, 252b, and 252c and a second sub-light blocking layer 454 may be disposed over the sensor passivation layer 244.

The light blocking layer 252a, 252b, and 252c and the second sub-light blocking layer 454 may include open areas. The second sub-color filters 4531b and 4532b may be disposed in the two open areas of the second subpixel SP2 area.

Referring to FIG. 8, the second sub-light blocking layer 454 may be disposed to overlap the second emitting element 220b. The width of the second sub-light blocking layer 454 may be smaller than the width of the light blocking layer 252a, 252b, and 252c.

Referring to FIG. 8, the second color filter 453b may include two second sub-color filters 4531b and 4532b. The second sub-color filters 4531b and 4532b may overlap the second emission area EA2 and may also overlap a portion of the non-emission area NEA surrounding the second emission area EA2.

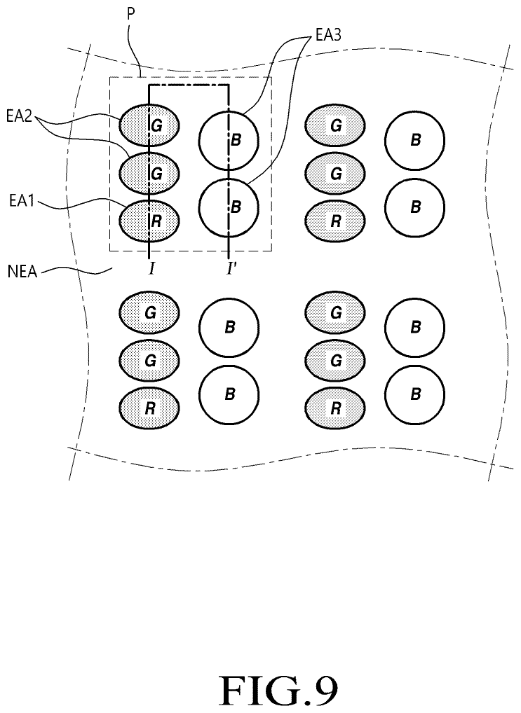

FIG. 9 illustrates another example plan diagram of a portion of the display area in the display device according to embodiments. In the following description, the features the same as or similar to those described with reference to FIGS. 1 to 8 are omitted or briefly described.

Referring to FIG. 9, the display device 100 according to embodiments may include a plurality of emission areas EA1, EA2, and EA3 and a non-emission area NEA surrounding the plurality of emission areas EA1, EA2, and EA3.

The first emission area EA1 may be a red emission area, the second emission area EA2 may be a green emission area, and the third emission area EA3 may be a blue emission area.

Referring to FIG. 9, the second emission area EA2 and the third emission area EA3 may respectively be divided into two emission areas. For example, a second color filter disposed in an area corresponding to the second emission area EA2 may be divided into two sub-color filters, and a third color filter disposed in an area corresponding to the third emission area EA3 may be divided into two sub-color filters.

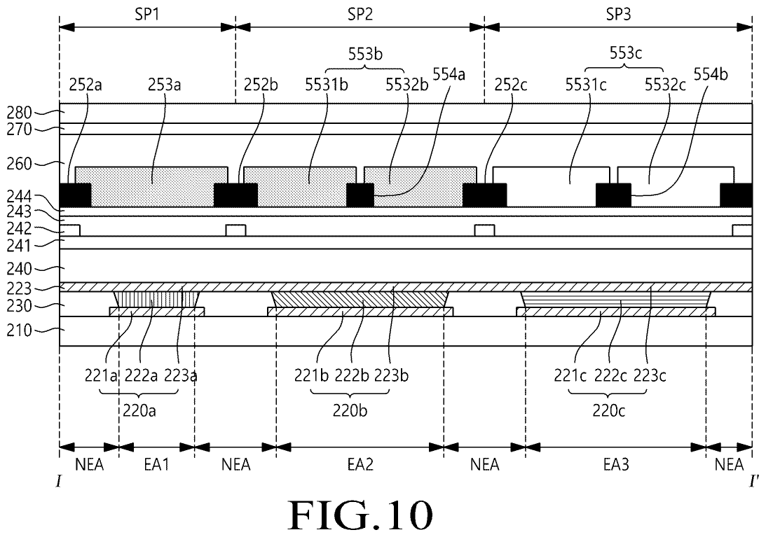

FIG. 10 illustrates an example cross-sectional diagram cut along line I-I′ of FIG. 9. In the following description, the features the same as or similar to those described with reference to FIGS. 1 to 9 are omitted or briefly described.

Referring to FIG. 10, the second subpixel SP2 may include a second color filter 553b divided into two second sub-color filters 5531b and 5532b. The third subpixel SP3 may include a third color filter 553c divided into two third sub-color filters 5531c and 5532c.

Referring to FIG. 10, a light blocking layer 252a, 252b, and 252c, a second sub-light blocking layer 554a, and a third sub-light blocking layer 554b may be disposed over the sensor passivation layer 244.

The light blocking layer 252a, 252b, and 252c and the sub-light blocking layers 554a and 554b may include open areas. The second sub-color filters 5531b and 5532b may be disposed in the two open areas of the second subpixel SP2 area. The third sub-color filters 5531c and 5532c may be disposed in the two open areas of the third subpixel SP3 area.

Referring to FIG. 10, the second sub-light blocking layer 554a may be disposed to overlap the second emitting element 220b. The width of the second sub-light blocking layer 554a may be smaller than the width of the light blocking layer 252a, 252b, and 252c. The third sub-light blocking layer 554b may be disposed to overlap the third emitting element 220c. The width of the third sub-light blocking layer 554b may be smaller than the width of the light blocking layer 252a, 252b, and 252c.

Referring to FIG. 10, the second color filter 553b may include the two second sub-color filters 5531b and 5532b. The second sub-color filters 5531b and 5532b may overlap the second emission area EA2 and may also overlap a portion of the non-emission area NEA surrounding the second emission area EA2. The third color filter 553c may include the two third sub-color filters 5531c and 5532c. The third sub-color filters 5531c and 5532c may overlap the third emission area EA3 and may also overlap a portion of the non-emission area NEA surrounding the third emission area EA3.

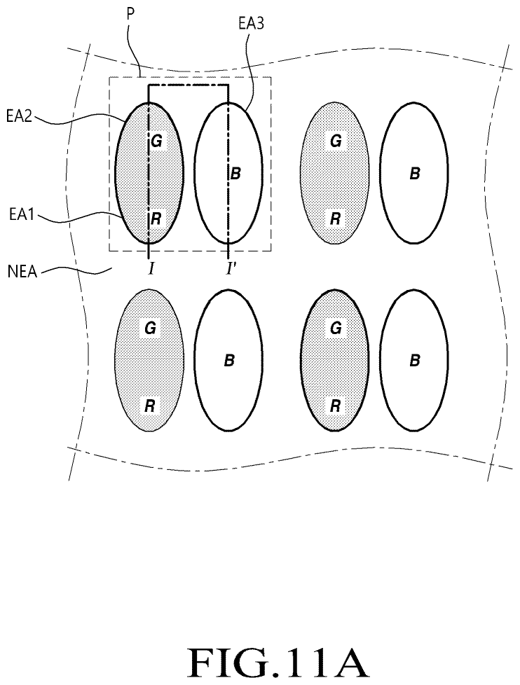

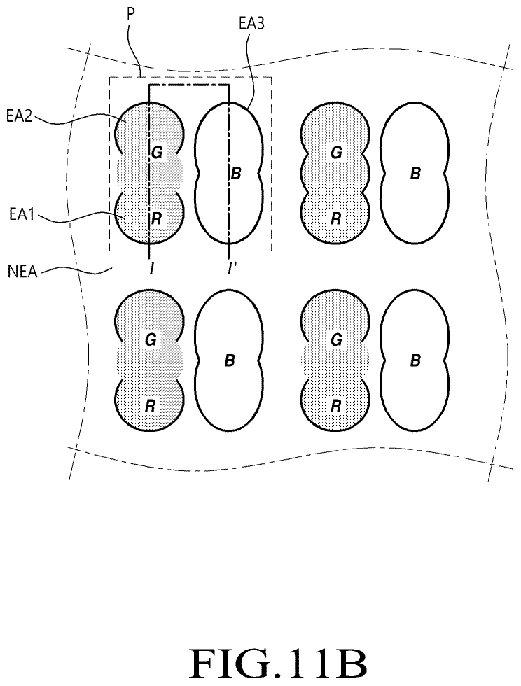

FIGS. 11A and 11B respectively illustrate another example plan diagram of a portion of the display area in the display device according to embodiments. In the following description, the features the same as or similar to those described with reference to FIGS. 1 to 10 are omitted or briefly described.

Referring to FIGS. 11A and 11B, the display device 100 according to embodiments may include a plurality of emission areas EA1, EA2, and EA3 and a non-emission area NEA surrounding the plurality of emission areas EA1, EA2, and EA3.

The first emission area EA1 may be a red emission area, the second emission area EA2 may be a green emission area, and the third emission area EA3 may be a blue emission area.

Referring to FIGS. 11A and 11B, the first emission area EA1 and the second emission area EA2 may be disposed integrally. For example, a first color filter disposed in an area corresponding to the first emission area EA1 and a second color filter disposed in an area corresponding to the second emission area EA2 may be disposed integrally with each other.

FIG. 11B differs from the first and second color filters shown in FIG. 11A in that the second color filter is divided into sub-color filters and disposed integrally with the first color filter. Further, FIG. 11B differs from the third color filter shown in FIG. 11A in that the third color filter is divided into sub-color filters which are disposed integrally with each other.

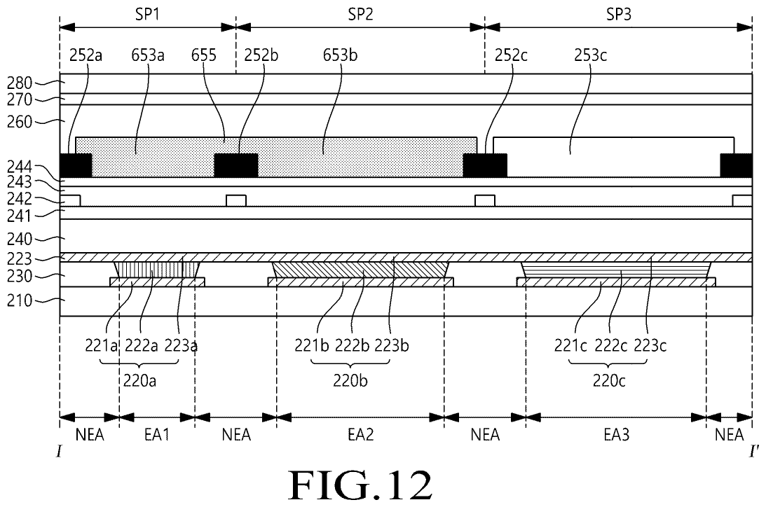

FIG. 12 illustrates an example cross-sectional diagram cut along line I-I′ of FIGS. 11A and 11B. In the following description, the features the same as or similar to those described with reference to FIGS. 1 to 11B are omitted or briefly described.

The plan diagrams shown in FIG. 11A and FIG. 11B have some differences, but the cross-sectional geometries thereof may be the same.

Referring to FIG. 12, the first color filter 653a and the second color filter 653b may be disposed integrally.

Referring to FIG. 12, a light blocking layer 252a, 252b, and 252c may be disposed over the sensor passivation layer 244.

The light blocking layer 252a, 252b, and 252c may include open areas. The color filters 653a, 653b, and 253c may be disposed in the open areas. A color pattern 655 provided as an extension of the first color filter 653a and the second color filter 653b may be disposed over the light blocking layer 252b disposed between the first color filter 653a and the second color filter 653b. That is, the first color filter 653a and the second color filter 653b may be disposed integrally to cover the light blocking layer 252b.

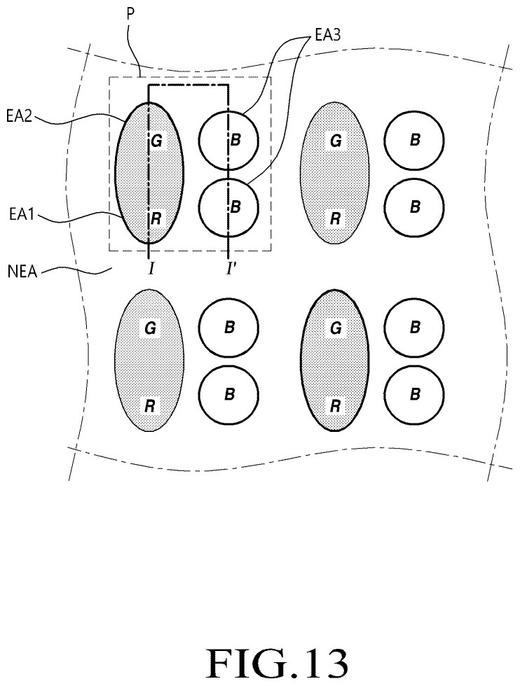

FIG. 13 illustrates another example plan diagram of a portion of the display area in the display device according to embodiments. In the following description, the features the same as or similar to those described with reference to FIGS. 1 to 12 are omitted or briefly described.

Referring to FIG. 13, the display device 100 according to embodiments may include a plurality of emission areas EA1, EA2, and EA3 and a non-emission area NEA surrounding the plurality of emission areas EA1, EA2, and EA3.

The first emission area EA1 may be a red emission area, the second emission area EA2 may be a green emission area, and the third emission area EA3 may be a blue emission area.

Referring to FIG. 13, the first emission area EA1 and the second emission area EA2 may be disposed integrally. For example, a first color filter disposed in an area corresponding to the first emission area EA1 and a second color filter disposed in an area corresponding to the second emission area EA2 may be disposed integrally with each other.

Referring to FIG. 13, the third emission area EA3 may be divided into two emission areas. For example, a third color filter disposed in an area corresponding to the third emission area EA3 may be divided into two sub-color filters.

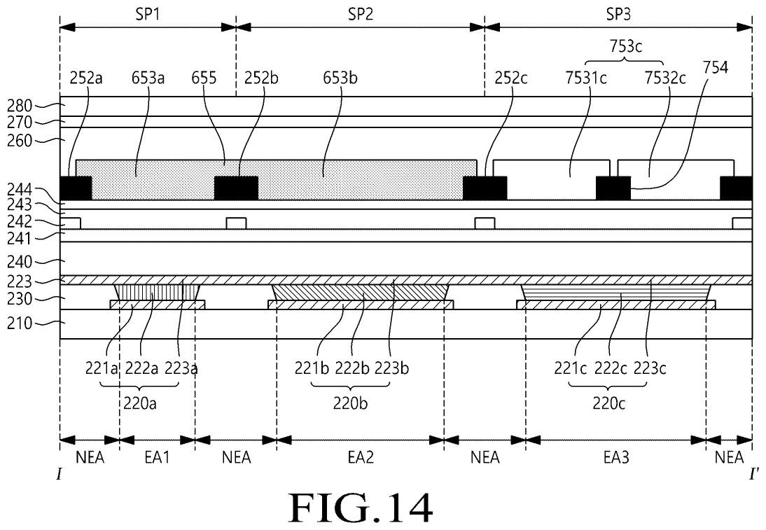

FIG. 14 illustrates an example cross-sectional diagram cut along line I-I′ of FIG. 13. In the following description, the features the same as or similar to those described with reference to FIGS. 1 to 13 are omitted or briefly described.

Referring to FIG. 14, the first color filter 653a and the second color filter 653b may be disposed integrally, and the third subpixel SP3 may include a third color filter 753c divided into two third sub-color filters 7531c and 7532c.

Referring to FIG. 14, the/a light blocking layer 252a, 252b, and 252c and a third sub-light blocking layer 754 may be disposed over a sensor passivation layer 244.

The light blocking layer 252a, 252b, and 252c and the third sub-light blocking layer 754 may include open areas. Color filters 653a, 653b, and 753c may be disposed in the open areas. A color pattern 655 provided as an extension of the first color filter 653a and the second color filter 653b may be disposed over the light blocking layer 252b disposed between the first color filter 653a and the second color filter 653b. That is, the first color filter 653a and the second color filter 653b may be disposed integrally to cover the light blocking layer 252b. The third sub-color filters 7531c and 7532c may be disposed in the two open areas of the third subpixel SP3 area.

Referring to FIG. 14, the third sub-light blocking layer 754 may be disposed to overlap the third emitting element 220c. The width of the third sub-light blocking layer 754 may be smaller than the width of the light blocking layer 252a, 252b, and 252c.

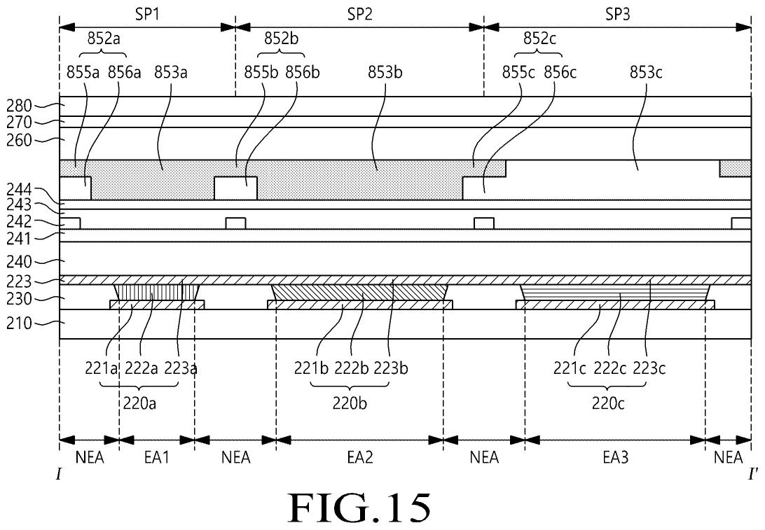

FIG. 15 illustrates an example cross-sectional diagram cut along line I-I′ of FIGS. 11A and 11B. In the following description, the features the same as or similar to those described with reference to FIGS. 1 to 14 are omitted or briefly described.

The plan diagrams shown in FIG. 11A and FIG. 11B have some differences, but the cross-sectional geometries thereof may be the same.

Referring to FIG. 15, a first color filter 853a and a second color filter 853b may be disposed integrally.

Referring to FIG. 15, a light blocking layer 852a, 852b, and 852c may be disposed over a sensor passivation layer 244.

The light blocking layer 852a, 852b, and 852c may be arranged by stacking a first color pattern 855a, 855b, and 855c, which is an extension of the first color filter 853a and the second color filter 853b, and a third color pattern 856a, 856b, and 856c having the same color as the third color filter 853c.

Referring to FIG. 15, the third color filter 853c and the third color pattern 856a, 856b, and 856c may be disposed first over the sensor passivation layer 244, followed by the first color filter 853a, the second color filter 853b, and the first color pattern 855a, 855b, and 855c.

When the light blocking layer 852a, 852b, and 852c is provided by stacking the third color pattern 856a, 856b, and 856c and the first color pattern 855a, 855b, and 855c, light emitted from the first emitting element 220a and the second light emitting irradiation 220b is blocked by the third color pattern 856a, 856b, and 856c and light emitted from the third emitting element 220c is blocked by the first color pattern 855a, 855b, and 855c. In this manner, the light blocking layer 852a, 852b, and 852c may serve to block light.

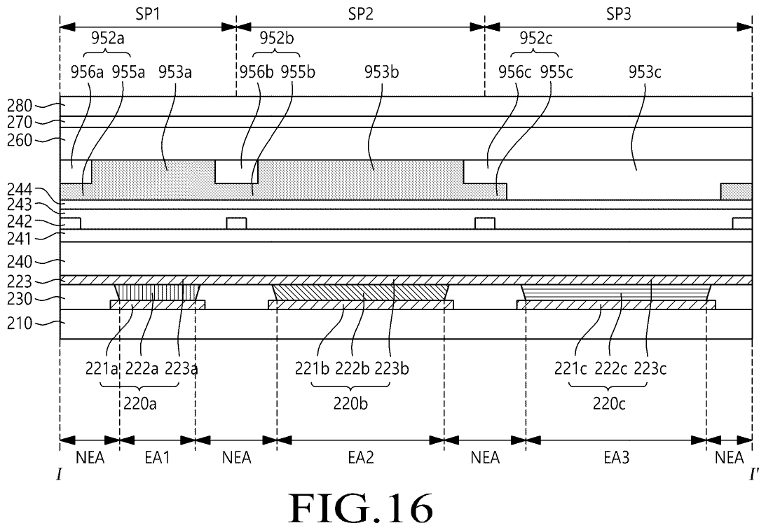

FIG. 16 illustrates an example cross-sectional diagram cut along line I-I′ of FIGS. 11A and 11B. In the following description, the features the same as or similar to those described with reference to FIGS. 1 to 15 are omitted or briefly described.

Referring to FIG. 16, a first color filter 953a and a second color filter 953b may be disposed integrally, similar to that shown in FIG. 15.

Referring to FIG. 16, a light blocking layer 952a, 952b, and 952c may be disposed over a sensor passivation layer 244.

The light blocking layer 952a, 952b, and 952c may be provided by stacking a first color pattern 955a, 955b, and 955c, provided as an extension of the first color filter 953a and the second color filter 953b, and a third color pattern 956a, 956b, and 956c of the same color as a third color filter 953c.

Referring to FIG. 16, the first color filter 953a, the second color filter 953b, and the first color pattern 955a, 955b, and 955c may be disposed first over the sensor passivation layer 244, followed by the third color filter 953c and the third color pattern 956a, 956b, and 956c.

When the light blocking layer 952a, 952b, and 952c is provided by stacking the first color pattern 955a, 955b, and 955c and the third color pattern 956a, 956b, and 956c, light emitted from the third emitting element 220c may be blocked by the first color patterns 955a, 955b, and 955c, and light emitted from the first emitting element 220a and the second light emitting element 220b may be blocked by the third color pattern 956a, 956b, and 956c.

### EXAMPLES

The display device according to embodiments will be described in detail below with reference to examples, but the embodiments are not limited to the following examples.

### Comparative Example 1

A green color filter was formed using a green pigment including a phthalocyanine compound including copper (Cu), represented by Comparative Compound below.

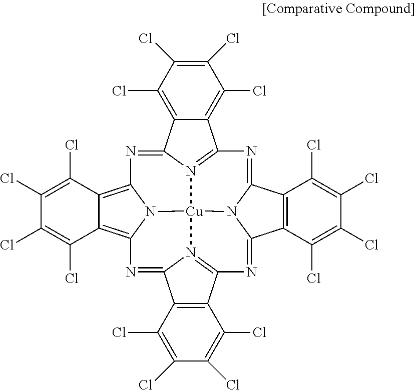

### Example 1

A color filter was formed using a color filter composition including a dye represented by an Embodiment Compound below, R¹ to R⁸ in Formula 1 are C₁, and C.I. Pigment Yellow 185 as a pigment, wherein 2% by weight of the dye represented by Formula 1 was included.

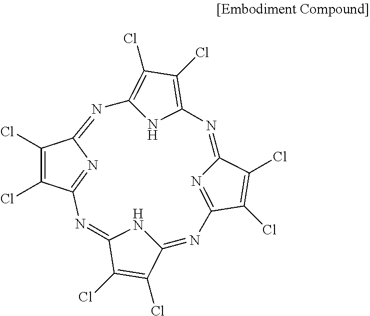 [SMILES: ClC1=C(Cl)c2nc1nc1[nH]c(nc3nc(nc4[nH]c(n2)c(Cl)c4Cl)C(Cl)=C3Cl)c(Cl)c1Cl]

### Example 2

A color filter was formed in the same manner as in Example 1, except that 5% by weight of the dye represented by the Embodiment Compound was included.

### Example 3

A color filter was formed in the same manner as in Example 1, except that 17% by weight of the dye represented by the Embodiment Compound was included.

### Example 4

A color filter was formed in the same manner as in Example 1, except that 20% by weight of the dye represented by the Embodiment Compound was included.

### Color Characteristic Evaluation

Color shift and luminance were measured at the center and an edge of the display area, respectively.

In Table 1 below, ΔGx and ΔGy represent color shifts of light through the color filters, and ΔGY represents luminance shifts of light through the color filters.

TABLE 1

| | Position | ΔGx | ΔGy | ΔGY % | Edge Blemish |
|---|---|---|---|---|---|
| Comp. | Center | −0.003 | −0.039 | −6% | Occurred |
| Ex. 1 | Edge | −0.001 | −0.023 | 1% | |
| Ex. 1 | Center | −0.002 | −0.002 | 3% | Not Occurred |
| | Edge | −0.003 | −0.002 | 3% | |
| Ex. 2 | Center | 0.001 | −0.002 | −3% | Not Occurred |
| | Edge | 0.000 | −0.003 | −2% | |
| Ex. 3 | Center | 0.002 | −0.002 | −1% | Not Occurred |
| | Edge | 0.001 | −0.002 | −1% | |
| Ex. 4 | Center | 0.001 | −0.001 | 3% | Not Occurred |
| | Edge | 0.001 | −0.002 | 1% | |

Referring to Table 1, it may be seen that Examples 1 to 4 formed using color filter compositions including a dye and a pigment according to embodiments exhibit less color shifts and luminance variations in the center and edges of the display area compared to Comparative Example 1 using a phthalocyanine-based compound including copper (Cu) in a green color filter.

It may also be seen that Comparative Example 1 has a luminance difference between the center and the edge of the display area, thereby resulting in an edge blemish in the display area, whereas Examples 1 to 4 experience a smaller luminance change between the center and the edge of the display area, thereby resulting in no edge blemish in the display area.

In other words, because each of the color filters according to embodiments does not include metals in the dye, light/water reactions with the central metal may be prevented, thereby resulting in less color variation and luminance variation between the center and the edges of the display area. Accordingly, the occurrence of edge blemishes of the display area may be reduced or prevented.

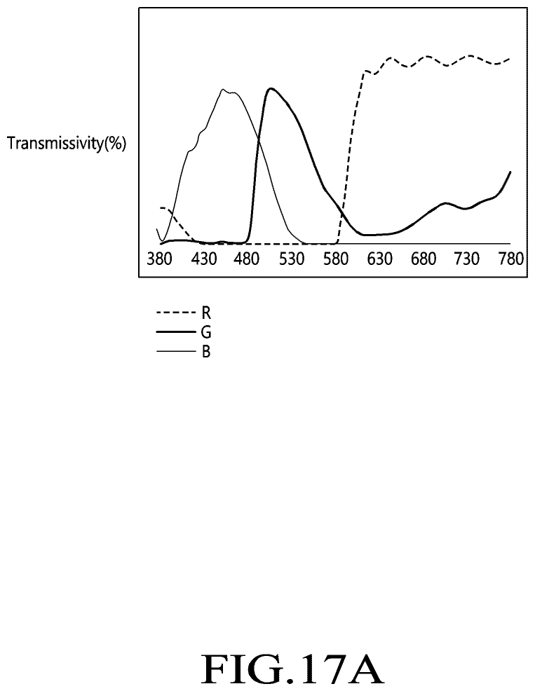

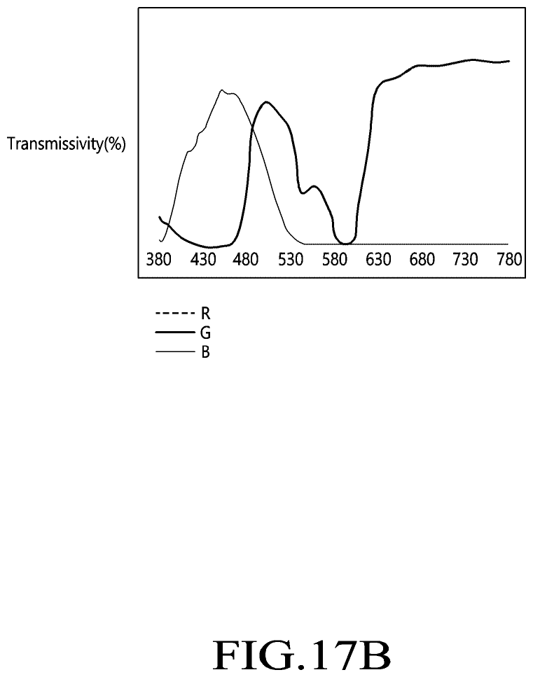

FIGS. 17A and 17B illustrate transmissivity graphs of a display device according to Comparative Example 2 and a display device according to Example 5 of the present disclosure.

The display device according to Comparative Example 2 shown in FIG. 17A is a display device having the structure shown in FIG. 4 without a polarizer and including red, green, and blue color filters over the emitting elements, respectively, wherein the green color filter is the color filter of Comparative Example 1.

The display device according to Example 5 of the present disclosure shown in FIG. 17B is a display device having the structure shown in FIG. 4, wherein the first color filter and the second color filter are the same as the color filters of Example 3.

Referring to FIG. 17A, in the display device according to Comparative Example 2, that the blue (B) color filter has a high transmissivity in a range between 420 nm and 460 nm, the green (G) color filter has a high transmissivity in a range between 520 nm and 560 nm, and the red (R) color filter has a high transmissivity in a range between 620 nm and 680 nm.

Referring to FIG. 17B, in the display device according to Example 5, the third color filter disposed in the third subpixel has a high transmissivity in a range between 420 nm and 460 nm. Further, the first and second (RG) color filters disposed in the first and second subpixels have a high transmissivity in a range between 500 nm and 540 nm and in a range between 630 nm and 680 nm and a low transmissivity in a range between 430 nm and 480 nm and in a range between 580 nm and 600 nm.

In other words, in the display device according to Example 5, the first and second (RG) color filters using the same color filter composition may transmit red (R) light and green (G) light but not blue (B) light. Thus, according to embodiments, instead of having separate color filters for the first subpixel emitting red (R) light and the second subpixel emitting green (G) light, the color filter including the same color filter composition may be used to emit red (R) light and green (G) light to the outside with less color shift and luminance reduction.

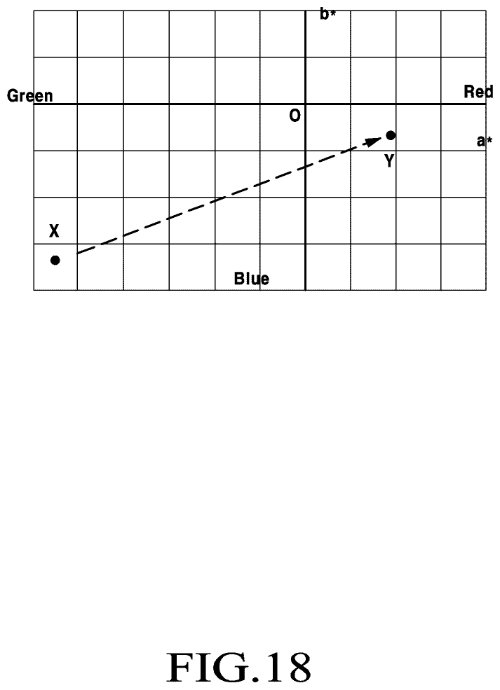

FIG. 18 illustrates a graph comparing the reflective visibility of a display device according to a comparative example and a display device according to an example of the present disclosure.

In the graph, X refers to the display device according to Comparative Example 2, and Y refers to the display device according to Example 5.

Referring to FIG. 18, it may be seen that the color coordinates of the display device in Example 2 are shifted toward green to indicate a greenish reflective visibility.

In contrast, it may be seen that the coordinates of the display device according to Example 5 are shifted to the vicinity of the zero point compared to the display device according to Comparative Example 2. In other words, the display device according to embodiments may improve a greenish reflective visibility.

The above-described embodiments of the present disclosure are briefly reviewed as follows.

Embodiments may provide a display device including: a substrate including a first emission area, a second emission area, a third emission area; emitting elements disposed in the first to third emission areas, respectively; an encapsulation layer covering the emitting elements; a first color filter, a second color filter, and a third color filter disposed over the encapsulation layer to correspond to the first to third emission areas, respectively; and a color filter composition including a dye and a pigment, wherein each of the first color filter and the second color filter includes the color filter composition.

In the display device according to embodiments, each of the first color filter and the second color filter may have a first peak absorption wavelength in a range between 430 nm and 480 nm and a second peak absorption wavelength in a range between 580 nm and 600 nm.

In the display device according to embodiments, each of the first color filter and the second color filter may have a transmissivity of 10% or less of an absorption peak in a range between 430 nm and 480 nm and a transmissivity of 10% or less of an absorption peak in a range between 580 nm and 600 nm.

In the display device according to embodiments, the color filter composition may include, by weight, more than 0% but no more than 20% of the dye of a sum of the dye and the pigment.

In the display device according to embodiments, the dye included in the color filter composition may be represented by the following Formula 1, the pigment may be a yellow pigment, and four central nitrogens (N) may not be metal-bonded.

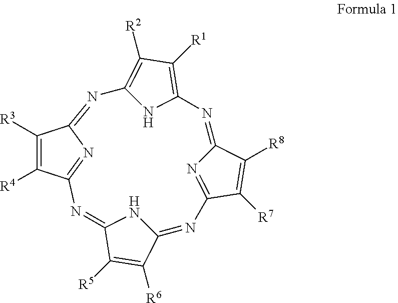

In the display device according to embodiments, the yellow pigment may be at least one selected from a group consisting of C.I. Pigment Yellow 11, 13, 24, 55, 108, 109, 110, 119, 138, 139, 150, 151, 154, 167, 168, 180, 185, and 231.

In the display device according to embodiments, the pigment may be represented by the following Formula 2.

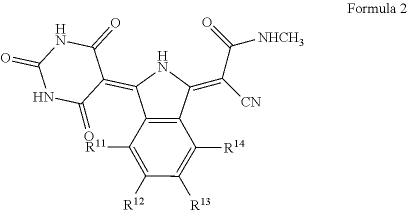

In the display device according to embodiments, the emitting elements may include: a first emitting element disposed in the first emission area and emitting red light; a second emitting element disposed in the second emission area and emitting green light; and a third emitting element disposed in the third emission area and emitting blue light.

In the display device according to embodiments, the display device may further include: a bank disposed over the substrate and defining the first to third emission areas; and a light blocking layer disposed over the encapsulation layer and overlapping the bank.

In the display device according to embodiments, the bank may be a black bank including a black component, and the light blocking layer may include a black component.

In the display device according to embodiments, the first color filter and the second color filter may be disposed integrally to cover the light blocking layer.

In the display device according to embodiments, the light blocking layer may include a stack of a color pattern including the color filter composition and a third color pattern having the same color as the third color filter.

In the display device according to embodiments, the display device may further include a touch electrode located over the encapsulation layer and disposed to overlap the bank.

In the display device according to embodiments, the light blocking layer may be disposed over the touch electrode.

In the display device according to embodiments, the area of the second color filter may be larger than the area of the first color filter and smaller than the area of the third color filter.

In the display device according to embodiments, at least one color filter among the first to third color filters may be divided into a plurality of sub-color filters.

In the display device according to embodiments, the sub-color filters may have a circular or polygonal shape and may be disposed integrally with each other.

A display device according to one or more exemplary embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, variable apparatuses, sliding apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game machines, notebook computers, monitors, cameras, camcorders, home appliances, etc., but embodiments of the present disclosure are not limited thereto.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate having a first emission area, a second emission area, and a third emission area;
emitting elements disposed in the first to third emission areas, respectively;
a first color filter, a second color filter, and a third color filter disposed over the emitting elements to correspond to the first to third emission areas, respectively; and
a color filter composition having a dye not including a central metal in a molecule and a pigment,
wherein each of the first color filter and the second color filter comprises the color filter composition.

2. The display device of claim 1, wherein each of the first color filter and the second color filter has a first peak absorption wavelength in a range between 430 nm and 480 nm and a second peak absorption wavelength in a range between 580 nm and 600 nm.

3. The display device of claim 1, wherein each of the first color filter and the second color filter has a transmissivity of 10% or less of an absorption peak in a range between 430 nm and 480 nm and a transmissivity of 10% or less of an absorption peak in a range between 580 nm and 600 nm.

4. The display device of claim 1, wherein each of the first color filter and the second color filter has a first peak absorption wavelength in a range between 430 nm and 480 nm and a transmissivity of 10% or less of the absorption peak in the range of the first peak absorption wavelength.

5. The display device of claim 1, wherein each of the first color filter and the second color filter has a second peak absorption wavelength in a range between 580 nm and 600 nm and a transmissivity of 10% or less of the absorption peak in the range of the second peak absorption wavelength.

6. The display device of claim 1, wherein the color filter composition comprises, by weight, more than 0% but more than 20% of the dye of a sum of the dye and the pigment.

7. The display device of claim 1, wherein the dye is represented by the following Formula 1, and the pigment is a yellow pigment, 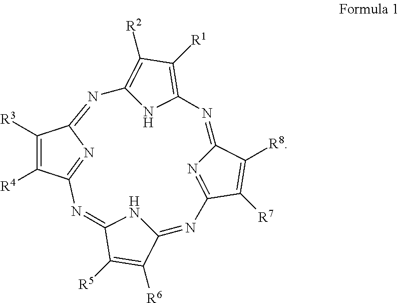
wherein in Formula 1, R¹ to R⁸ are selected independently of each other from a group consisting of hydrogen, a halogen atom, a cyano group, an amino group, a nitro group, an amide group, a carbonyl group, a hydroxyl group, a sulfonyl group, a C₁-C₃₀ alkyl group, a C₂-C₃₀ alkenyl group, a C₂-C₃₀ alkynyl group, a C₁-C₃₀ alkoxy group, a C₆-C₅₀ aryl group, and a C₂-C₅₀ heteroaryl group,
in R¹ to R⁸ of Formula 1, the alkyl, alkenyl, alkynyl, alkoxy, aryl, and heteroaryl groups, each independently, are further substituted with one or more substituents selected from a group consisting of deuterium, tritium, a nitro group, a halogen, a cyano group, an amino group, a C₁-C₂₀ alkyl group, a C₂-C₂₀ alkenyl group, a C₂-C₂₀ alkynyl group, a C₁-C₂₀ alkoxy group, a C₆-C₂₀ aryl group, a C₆-C₂₀ aryl group substituted with deuterium, and a C₂-C₂₀ heteroaryl group, and
four central nitrogens (N) are not metal-bonded.

8. The display device of claim 7, wherein the yellow pigment is at least one selected from a group consisting of C.I. Pigment Yellow 11, 13, 24, 55, 108, 109, 110, 119, 138, 139, 150, 151, 154, 167, 168, 180, 185, and 231.

9. The display device of claim 7, wherein the pigment is represented by the following Formula 2, 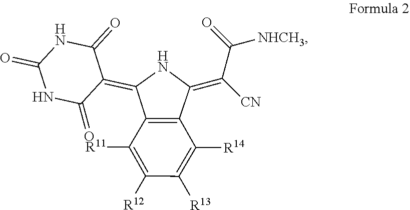
wherein in Formula 2, R¹¹ to R¹⁴ are selected independently of each other from a group consisting of hydrogen, a halogen atom, a cyano group, an amino group, a nitro group, an amide group, a carbonyl group, a hydroxyl group, a sulfonyl group, a C₁-C₃₀ alkyl group, a C₂-C₃₀ alkenyl group, a C₂-C₃₀ alkynyl group, a C₁-C₃₀ alkoxy group, a C₆-C₅₀ aryl group, and a C₂-C₅₀ heteroaryl group, and
in R¹¹ to R¹⁴ of Formula 2, the alkyl, alkenyl, alkynyl, alkoxy, aryl, and heteroaryl groups, each independently, are further substituted with one or more substituents selected from a group consisting of deuterium, tritium, a nitro group, a halogen, a cyano group, an amino group, a C₁-C₂₀ alkyl group, a C₂-C₂₀ alkenyl group, a C₂-C₂₀ alkynyl group, a C₁-C₂₀ alkoxy group, a C₆-C₂₀ aryl group, a C₆-C₂₀ aryl group substituted with deuterium, and a C₂-C₂₀ heteroaryl group.

10. The display device of claim 1, wherein the emitting elements comprise:
a first emitting element disposed in the first emission area and emitting red light;
a second emitting element disposed in the second emission area and emitting green light; and
a third emitting element disposed in the third emission area and emitting blue light.

11. The display device of claim 1, further comprising:
a bank disposed over the substrate and defining the first to third emission areas; and
a light blocking layer disposed over the encapsulation layer and overlapping the bank.

12. The display device of claim 11, wherein the bank comprises a black component.

13. The display device of claim 11, wherein the first color filter and the second color filter are disposed integrally to cover the light blocking layer.

14. The display device of claim 11, wherein the light blocking layer comprises a stack of a color pattern comprising the color filter composition and a third color pattern having the same color as the third color filter.

15. The display device of claim 11, further comprising a touch electrode located over the encapsulation layer and disposed to overlap the bank.

16. The display device of claim 15, wherein the light blocking layer is disposed over the touch electrode to overlap the touch electrode.

17. The display device of claim 16, wherein the display device further comprises a passivation layer disposed over the first color filter, the second color filter, the third color filter, and a black adhesive layer.

18. The display device of claim 1, wherein an area of the second color filter is larger than an area of the first color filter and smaller than an area of the third color filter.

19. The display device of claim 1, wherein at least one color filter among the first to third color filters is divided into a plurality of sub-color filters.

20. The display device of claim 19, wherein the sub-color filters have a circular or polygonal shape and are disposed integrally with each other.
